(19) United States
(12) Patent Application Publication
(10) Pub. No.: US 2022/0155152 A1
(43) Pub. Date: May 19, 2022

(54) INFRARED PHOTODETECTION DEVICE, INFRARED PHOTODETECTION PROCESS, COMPUTER PROGRAM, AND COMPUTER-READABLE STORAGE MEDIUM CONTAINING PROGRAM

(71) Applicant: SHARP KABUSHIKI KAISHA, Sakai City, Osaka (JP)

(72) Inventor: TAZUKO KITAZAWA, Sakai City, Osaka (JP)

(21) Appl. No.: 17/438,371

(22) PCT Filed: Mar. 11, 2020
(86) PCT No.: PCT/JP2020/010609

§ 371 Date: Sep. 10, 2021

(30) Foreign Application Priority Data
Mar. 12, 2019 (JP) 2019-045184

(51) Int. Cl. G01J 5/28; G01J 5/60

(52) U.S. Cl. CPC G01J 5/28; H01L 31/035218; G01J 5/60

(57) ABSTRACT

An infrared photodetection device (10) includes a detection unit (1) and a calculation unit (3). The detection unit (1) detects infrared light in a particular, first wavelength range. The calculation section (3) calculates an optical signal component detected by the detection unit 1 from a detection value of the detection unit (1) and a thermal signal component representing an amount of change of a thermal signal caused by a rise in temperature when infrared light is incident on the detection unit (1), and calculates the temperature of a measurement object (30) from the calculated optical signal component and the calculated thermal signal component.

### TECHNICAL FIELD

The present invention relates to infrared photodetection devices, infrared photodetection processes, computer programs, and computer-readable storage media containing a program.

### BACKGROUND ART

Japanese Unexamined Patent Application Publication, Tokukai, No. 2007-183207 describes a conventionally known radiation thermometer. The radiation thermometer described in Japanese Unexamined Patent Application Publication, Tokukai, No. 2007-183207 includes a first sensor, a second sensor, a transmittance storage unit, a sensor correlation computation unit, a temperature correlation information storage unit, and a temperature computation unit. The first sensor detects the reception light level of transmitted light passing through a measurement object in a first wavelength range in which the measurement object has a lower emissivity for radiation light radiating from the measurement object than a prescribed value. The second sensor detects the reception light levels of the transmitted light and the radiation light in a second wavelength range in which the measurement object has, for the radiation light, an emissivity equal to a prescribed value that is higher than the emissivity in the first wavelength range. The transmittance storage unit stores both a constant related to a first transmittance of the measurement object for light in the first wavelength range and a constant related to a second transmittance of the measurement object for light in the second wavelength range. The sensor correlation computation unit stores a correlation between the level of radiation light radiating from a heat source as received by the first sensor and the level of radiation light radiating from the heat source as received by the second sensor. The sensor correlation computation unit also calculates the radiation level of the heat source in the second wavelength range from the correlation by using a value obtained by dividing the level of the light received and detected by the first sensor by the first transmittance stored in the transmittance storage unit. The temperature correlation information storage unit stores a correlation between the temperature of the measurement object and the reception light level detected by the second sensor of radiation light radiating from the measurement object. The temperature computation unit calculates the temperature of the measurement object on the basis of the radiation level of the heat source in the second wavelength range calculated by the sensor correlation computation unit, the transmittance constant of the measurement object stored in the transmittance storage unit, and the level of reception light detected by the second sensor, by using a prescribed correlation equation stored in the temperature correlation information storage unit.

Japanese Unexamined Patent Application Publication, Tokukai, No. 2012-202934 describes a conventionally known thermal imaging method. The imaging method described in Japanese Unexamined Patent Application Publication, Tokukai, No. 2012-202934 involves: estimating an infrared detection value from a thermal responsivity of an infrared imaging device and a difference between a first detection value and a second detection value; and estimating an infrared detection value of the infrared imaging device for the current scan period from a rate of change of the detection value of the infrared imaging device from the immediately preceding scan period to the current scan period, to estimate the temperature of an object for the current scan period.

Japanese Unexamined Patent Application Publication, Tokukai, No. 2017-184017 describes a conventionally known infrared photodetection device. The infrared photodetection device described in Japanese Unexamined Patent Application Publication, Tokukai, No. 2017-184017 calculates a difference between a first signal representing the amount of dark current flowing in a light-receiving element and a second signal representing the amount of current flowing in the light-receiving element during image capturing, to obtain photocurrent data. The infrared photodetection device includes a temperature sensor, so that the infrared photodetection device can measure the amount of dark current in response to a change in the temperature detected by the temperature sensor to generate a first signal representing the measurement of the amount of dark current. Patent Literature 3 thus discloses: detecting temperature around an infrared photodetection device by using a temperature sensor; and in response to a change in temperature around the infrared photodetection device, subtracting a first signal representing post-change temperature from a second signal to obtain photocurrent data.

### SUMMARY OF INVENTION

Japanese Unexamined Patent Application Publication, Tokukai, No. 2007-183207, Japanese Unexamined Patent Application Publication, Tokukai, No. 2012-202934, and Japanese Unexamined Patent Application Publication, Tokukai, No. 2017-184017 all calculate temperature using a single wavelength range. It is therefore difficult to reduce error in calculating the temperature of a measurement object in these techniques. In addition, Japanese Unexamined Patent Application Publication, Tokukai, No. 2007-183207 and Japanese Unexamined Patent Application Publication, Tokukai, No. 2012-202934 lack the concept of using both thermal response and optical response.

In view of these issues, the present invention, in an embodiment thereof, provides an infrared photodetection device allowing for less error in calculating the temperature of a measurement object.

The present invention, in another embodiment thereof, provides an infrared photodetection process allowing for less error in calculating the temperature of a measurement object.

The present invention, in a further embodiment thereof, provides a computer program for implementing a temperature calculation process allowing for less error in calculating the temperature of a measurement object.

The present invention, in still another embodiment thereof, provides a computer-readable storage medium containing a computer program for implementing a temperature calculation process allowing for less error in calculating the temperature of a measurement object.

### Configuration 1

The present invention, in an embodiment thereof, is directed to an infrared photodetection device including: a detection unit and a calculation unit. The detection unit includes a detection element configured to detect infrared light in a first wavelength range and detect infrared light in a second wavelength range lying within the first wavelength range, the second wavelength range having a central wavelength toward a short wavelength end and/or a long wavelength end with respect to a central wavelength of the first wavelength range. The calculation unit includes a computation section capable of calculating temperature of an object from a first detection value obtained when infrared light is detected in the first wavelength range by the detection element and a second detection value obtained when infrared light is detected in the second wavelength range by the detection element.

### Configuration 2

In Configuration 1, the calculation unit calculates a ratio of the first and second detection values and calculates the temperature of the object from the calculated ratio.

### Configuration 3

In Configuration 1 or 2, the calculation unit calculates a thermal signal component from the first detection value, the thermal signal component representing an amount of change of a thermal signal caused by a rise in temperature when infrared light in the first wavelength range is incident on the detection element, calculates an optical signal component from the second detection value, the optical signal component being generated by infrared light in the second wavelength range, and calculates the temperature of the object from the calculated optical signal component and the calculated thermal signal component.

### Configuration 4

In Configuration 3, the calculation unit calculates the optical signal component and the thermal signal component from a time response of a detection value detected by the detection element and calculates the temperature of the object from the calculated optical signal component and the calculated thermal signal component.

### Configuration 5

The present invention, in an embodiment thereof, is directed to an infrared photodetection device including: a detection unit and a calculation unit. The detection unit includes a detection element configured to detect infrared light in a first wavelength range, detect infrared light in a third wavelength range lying within the first wavelength range, the third wavelength range having a central wavelength toward a short wavelength end with respect to a central wavelength of the first wavelength range, and detect infrared light in a fourth wavelength range lying within the first wavelength range, the fourth wavelength range having a central wavelength toward a long wavelength end with respect to the central wavelength of the first wavelength range. The calculation unit includes a computation section capable of calculating temperature of an object from a first detection value obtained when infrared light is detected in the first wavelength range by the detection element, a third detection value obtained when infrared light is detected in the third wavelength range by the detection element, and a fourth detection value obtained when infrared light is detected in the fourth wavelength range by the detection element.

### Configuration 6

In Configuration 5, the calculation unit calculates a first ratio obtained by dividing the first detection value by the third detection value, a second ratio obtained by dividing the first detection value by the fourth detection value, and a third ratio obtained by dividing the fourth detection value by the third detection value and calculates, as the temperature of the object, one of a first temperature of the object calculated from the first ratio and a second temperature of the object calculated from the second ratio that differs more from a third temperature of the object calculated from the third ratio.

### Configuration 7

In any one of Configurations 1 to 5, the first wavelength range lies within an atmospheric window.

### Configuration 8

In Configuration 7, the first wavelength range lies within any one of wavelength ranges of 3.4 to 4.2 μm, 4.4 to 5.5 μm, and 8 to 14 μm.

### Configuration 9

In any one of Configurations 1 to 5, the first wavelength range is a transmission wavelength range of an optical element disposed between the object and the detection unit.

### Configuration 10

In Configuration 5, the detection unit further includes: a first filter for detecting the first wavelength range; a second filter for detecting the third wavelength range; and a third filter for detecting the fourth wavelength range.

### Configuration 11

In any one of Configurations 1 to 9, the detection element includes a quantum-dot layer or a quantum-well layer.

### Configuration 12

In Configuration 11, the infrared photodetection device selects the third wavelength range and the fourth wavelength range by applying a voltage to the detection element.

### Configuration 13

In any one of Configurations 1 to 10, the detection element includes: a first detection element configured to detect infrared light in the first wavelength range; and a second detection element configured to detect infrared light in the second wavelength range. The first detection element is a thermal element.

### Configuration 14

In Configuration 13, the second detection element includes a detection element having a function identical to a function of the first detection element.

### Configuration 15

The present invention, in an embodiment thereof, is directed to an infrared photodetection process including: a first step of a detection element detecting infrared light in a first wavelength range and detecting infrared light in a second wavelength range lying within the first wavelength range, the second wavelength range having a central wavelength toward a short wavelength end or a long wavelength end with respect to a central wavelength of the first wavelength range; and a second step of receiving a first detection value obtained when infrared light is detected in the first wavelength range by the detection element and a second detection value obtained when infrared light is detected in the second wavelength range by the detection element, calculating a ratio of the received first and second detection values, and calculating temperature of an object from the calculated ratio.

### Configuration 16

In Configuration 15, the second step calculates a thermal signal component from the first detection value, the thermal signal component representing an amount of change of a thermal signal caused by a rise in temperature when infrared light in the first wavelength range is incident on the detection element, calculates an optical signal component from the second detection value, the optical signal component being generated by infrared light in the second wavelength range, and calculates the temperature of the object from the calculated optical signal component and the calculated thermal signal component.

### Configuration 17

In Configuration 15, the second wavelength range includes a third wavelength range lying within the first wavelength range and a fourth wavelength range lying within the first wavelength range, the third wavelength range having a central wavelength toward a short wavelength end with respect to a central wavelength of the first wavelength range, the fourth wavelength range having a central wavelength toward a long wavelength end with respect to the central wavelength of the first wavelength range, and the second step calculates a first ratio obtained by dividing the first detection value by a third detection value, a second ratio obtained by dividing the first detection value by a fourth detection value, and a third ratio obtained by dividing the fourth detection value by the third detection value from the first detection value, the third detection value, and the fourth detection value, the third detection value being obtained when infrared light is detected in the third wavelength range by the detection element, the fourth detection value being obtained when infrared light is detected in the fourth wavelength range by the detection element, and calculates, as the temperature of the object, one of a first temperature of the object calculated from the first ratio and a second temperature of the object calculated from the second ratio that differs more from a third temperature of the object calculated from the third ratio.

### Configuration 18

The present invention, in an embodiment thereof, is directed to a computer program for causing a computer to calculate temperature of an object from a first detection value obtained when infrared light is detected in a first wavelength range by a detection element and a second detection value obtained when infrared light is detected in a second wavelength range by the detection element, the second wavelength range lying within the first wavelength range and having a central wavelength toward a short wavelength end or a long wavelength end with respect to a central wavelength of the first wavelength range, the computer program causing the computer to implement: a first step of a reception means receiving the first detection value and the second detection value; a second step of a calculation means calculating a ratio of the first and second detection values from the first and second detection values received in the first step; and a third step of the calculation means calculating the temperature of the object from the calculated ratio.

### Configuration 19

In Configuration 18, the second wavelength range includes a third wavelength range lying within the first wavelength range and a fourth wavelength range lying within the first wavelength range, the third wavelength range having a central wavelength toward a short wavelength end with respect to the central wavelength of the first wavelength range, the fourth wavelength range having a central wavelength toward a long wavelength end with respect to the central wavelength of the first wavelength range, the reception means, in the first step, receives the first detection value, a third detection value obtained when infrared light is detected in the third wavelength range by the detection element, and a fourth detection value obtained when infrared light is detected in the fourth wavelength range by the detection element, the calculation means, in the second step, calculates a first ratio obtained by dividing the first detection value by the third detection value, a second ratio obtained by dividing the first detection value by the fourth detection value, and a third ratio obtained by dividing the fourth detection value by the third detection value from the first detection value, the third detection value, and the fourth detection value, and the calculation means, in the third step, calculates a first temperature of the object from the first ratio, a second temperature of the object from the second ratio, and a third temperature of the object from the third ratio and calculates, as the temperature of the object, one of the first and second temperatures that differs more from the third temperature.

### Configuration 20

The present invention, in an embodiment thereof, is directed to a computer-readable storage medium containing the computer program of Configuration 18 or 19.

### Advantageous Effects of Invention

The present invention allows for less error in calculating the temperature of a measurement object.

### BRIEF DESCRIPTION OF DRAWINGS

FIG. 1 is a schematic view of an infrared photodetection device in accordance with Embodiment 1 of the present invention.

FIG. 2 is a cross-sectional view of a quantum-dot infrared photodetector in the detection element shown in FIG. 1.

FIG. 3 is a first manufacturing process diagram of a method of manufacturing the quantum-dot infrared photodetector shown in FIG. 2.

FIG. 4 is a second manufacturing process diagram of the method of manufacturing the quantum-dot infrared photodetector shown in FIG. 2.

FIG. 5 is a graph representing a relationship between black-body radiation intensity and wavelength.

FIG. 6 is a diagram representing a relationship between transmittance and wavelength.

FIG. 7 is a diagram representing a relationship between detection sensitivity and wavelength.

FIG. 8 is a flow chart representing an infrared photodetection process in accordance with Embodiment 1.

FIG. 9 is a diagram representing a relationship between the ratio of integrated values of black-body radiation brightness and the temperature of an object.

FIG. 10 is a schematic view of an infrared photodetection device in accordance with Embodiment 2.

FIG. 11 is a schematic view of another infrared photodetection device in accordance with Embodiment 2.

FIG. 12 is a flow chart representing an infrared photodetection process in accordance with Embodiment 2.

FIG. 13 is a schematic view of an infrared photodetection device in accordance with Embodiment 3.

FIG. 14 is a set of conceptual drawings illustrating a time response of a detection signal.

FIG. 15 is a flow chart representing an infrared photodetection process in accordance with Embodiment 3.

FIG. 16 is another flow chart representing infrared photodetection process in accordance with Embodiment 3.

FIG. 17 is a schematic view of an infrared photodetection device in accordance with Embodiment 4.

FIG. 18 is a diagram representing a relationship between the transmittance of a wavelength filter and wavelength.

FIG. 19 is a diagram representing a relationship between black-body radiation brightness, emissivity, and wavelength.

FIG. 20 is a diagram representing a relationship between a detection ratio and temperature.

FIG. 21 is a flow chart representing an infrared photodetection process in accordance with Embodiment 4.

FIG. 22 is a schematic view of an infrared photodetection device in accordance with Embodiment 5.

FIG. 23 is a diagram representing a relationship between the detection sensitivity of the detection element shown in FIG. 22 and wavelength.

FIG. 24 is a flow chart representing an infrared photodetection process in accordance with Embodiment 5.

FIG. 25 is a schematic view of an infrared photodetection device in accordance with Embodiment 6.

FIG. 26 is a diagram representing a relationship between the detection sensitivity of the detection element shown in FIG. 25 and wavelength.

FIG. 27 is a flow chart representing an infrared photodetection process in accordance with Embodiment 6.

### DESCRIPTION OF EMBODIMENTS

The following will describe embodiments of the present invention in detail with reference to drawings. Identical and equivalent members will be denoted by the same reference signs throughout the drawings, and description thereof is not repeated.

A description is now given of some of the terms used in this specification.

A “quantum-dot layer” is composed primarily of quantum dots, a wetting layer, an intermediate layer, a quantum-dot underlayer, a quantum-dot partial capping layer, and an insertion layer.

“Quantum dots” are semiconductor fine particles having a particle size of less than or equal to 100 nm and surrounded by a semiconductor material that has a larger band gap than does the semiconductor material for the quantum dots. In Stranski-Krastanov (S-K) growth, a wetting layer is formed before a transition to quantum dot growth.

A “quantum-dot underlayer” is an underlayer for the growth of quantum dots and a wetting layer and is made of a semiconductor material that has a larger band gap than does the semiconductor material for the quantum dots.

A “quantum-dot partial capping layer” is a layer that grows on quantum dots and is made of a semiconductor material that has a larger band gap than does the semiconductor material for the quantum dots, and covers at least parts of the quantum dots. FIG. 2 described below shows a flat partial capping layer, which may alternatively be shaped to match the shape of the quantum dots. FIG. 2 also shows the partial capping layer with a thickness that is greater than or equal to the height of the quantum dots. The thickness may alternatively be less than or equal to the height of the quantum dots.

An “intermediate layer” is a base layer for a quantum-dot layer and is made of a semiconductor material that has a larger band gap than does the semiconductor material for the quantum dots. The intermediate layer may be made of the same semiconductor material as the quantum-dot underlayer and the quantum-dot partial capping layer. The intermediate layer here refers to an intermediate layer in a quantum-dot layer.

A “quantum-well layer” includes, for example, quantum wells and an intermediate layer.

“Quantum wells” form a semiconductor layer with a thickness of less than or equal to 100 nm and is interposed between semiconductor materials that have a larger band gap than does the semiconductor material for the quantum wells.

An “intermediate layer” is made of a semiconductor material that has a larger band gap than does the semiconductor material for the quantum wells and has the same meaning as an intermediate layer in a quantum-dot layer. The intermediate layer here refers to an intermediate layer in a quantum-well layer.

### Embodiment 1

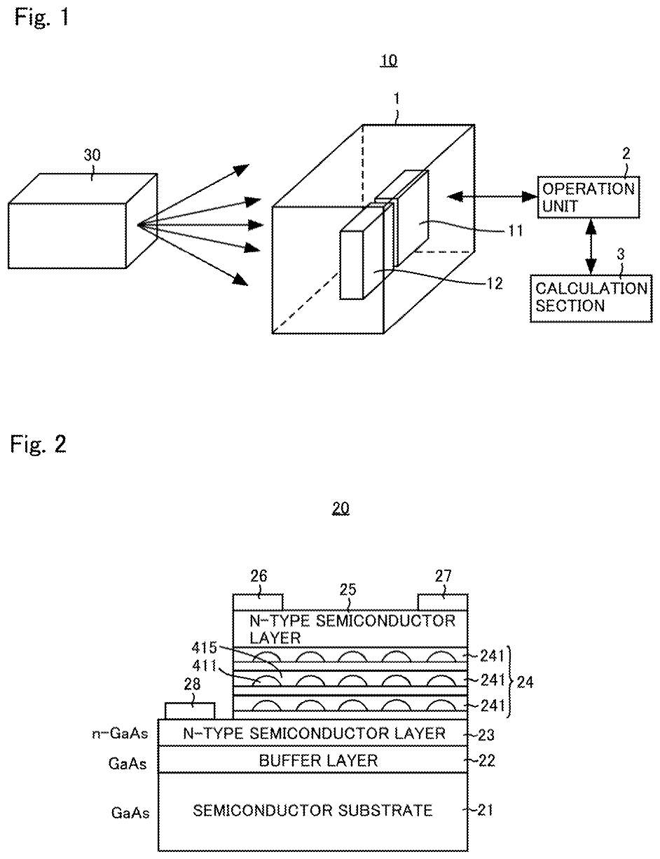

FIG. 1 is a schematic view of an infrared photodetection device in accordance with Embodiment 1 of the present invention. Referring to FIG. 1, an infrared photodetection device 10 in accordance with Embodiment 1 of the present invention includes a detection unit 1, an operation unit 2, and a calculation section 3.

The detection unit 1 includes a detection element 11 and a reference element 12. The detection element 11 includes a quantum-dot infrared photodetector (QDIP) or a quantum-well infrared photodetector (QWIP). The quantum-dot infrared photodetector or the quantum-well infrared photodetector may be either a single element or an imager. Under an application voltage from the operation unit 2, the detection element 11 detects infrared light, emitted by a measurement object 30, in a certain specific wavelength range (second wavelength range) and outputs an analog signal as a detection spectrum to the operation unit 2. The analog signal is a voltage or current signal in accordance with the radiation intensity of the detected infrared light. The second wavelength range is a range of wavelengths of the light to which the detection unit 1 has detection sensitivity.

The reference element 12 outputs a detection intensity that changes with the heat produced by incident light. The reference element 12 is, for example, a thermal element. Specific examples of such a thermal element include a bolometer and a thermopile. The reference element 12 detects a thermal signal component that represents an amount of change of a thermal signal caused by a rise in temperature under incident infrared light and outputs the detected thermal signal component to the operation unit 2. The reference element 12 detects a thermal signal component, but not an optical signal component. More particularly, the reference element 12 detects the thermal signal component detected by the detection element 11, but not the optical signal component detected by the detection element 11. The reference element 12 detects a thermal signal component in a particular range that is referred to as a first wavelength range. The first wavelength range represents an overlap between a wavelength range (A) of the infrared light radiating from an object and being actually incident on the reference element 12 and a wavelength range (B) of the infrared light detectable as a thermal signal component by the reference element 12. The wavelength range (A) varies with the transmittance of infrared light from the object to the reference element 12 (hereinafter, the “transmittance”). The wavelength range (B) is a range of wavelengths of the light to which the reference element 12 has detection sensitivity.

The operation unit 2 applies an application voltage V to the detection element 11. The application voltage V may have a constant value. Alternatively, the application voltage may be cyclically changed as in, for example, V=V0+ΔV sin(2λt/T_{S}) when the detection element 11 detects different wavelengths under different application voltages. V0 and ΔV are set in accordance with the desired detectable wavelength range. T_{S} is a time cycle at which the application voltage V is modulated.

The operation unit 2 receives, from the detection element 11, a detection spectrum detected by the detection element 11 under the application voltage V and outputs the received detection spectrum to the calculation section 3. The operation unit 2 also receives a thermal signal component from the reference element 12 and outputs the received thermal signal component to the calculation section 3.

The calculation section 3 receives a detection spectrum and a thermal signal component from the operation unit 2 to calculate the temperature of the measurement object 30 from the received detection spectrum and thermal signal component by using a technique which will be detailed later.

FIG. 2 is a cross-sectional view of a quantum-dot infrared photodetector in the detection element 11 shown in FIG. 1. Referring to FIG. 2, a quantum-dot infrared photodetector 20 includes a semiconductor substrate 21, a buffer layer 22, n-type semiconductor layers 23 and 25, a photoelectric conversion layer 24, and electrodes 26 to 28.

The buffer layer 22 is disposed on the semiconductor substrate 21 in contact with one of the surfaces of the semiconductor substrate 21. The n-type semiconductor layer 23 is disposed on the buffer layer 22 in contact with the buffer layer 22.

The photoelectric conversion layer 24 is disposed on the n-type semiconductor layer 23 in contact with the n-type semiconductor layer 23. The n-type semiconductor layer 25 is disposed on the photoelectric conversion layer 24 in contact with the photoelectric conversion layer 24.

The electrodes 26 and 27 are disposed on the n-type semiconductor layer 25 in contact with the n-type semiconductor layer 25 and are separated by a distance from each other. The electrode 28 is disposed on the n-type semiconductor layer 23 in contact with the n-type semiconductor layer 23.

The semiconductor substrate 21 is made of, for example, semi-insulating GaAs. A buffer layer 23 is made of, for example, GaAs. The buffer layer 23 has a thickness of, for example, 100 nm to 500 nm.

The n-type semiconductor layers 23 and 25 are made of, for example, n-GaAs. The n-type semiconductor layers 23 and 25 each have a thickness of, for example, 100 nm to 1000 nm.

The electrodes 26 to 28 are n-type electrodes and made of, for example, any of Au/AuGeNi, AuGe/Ni/Au, Au/Ge, and Au/Ge/Ni/Au. The electrodes 26 to 28 each have a thickness of, for example, 10 nm to 500 nm.

The photoelectric conversion layer 24 has a layered structure including a stack of quantum-dot layers 241. FIG. 2 shows a stack of three quantum-dot layers 241. The quantum-dot infrared photodetector 20 however needs only to include a stack of two or more quantum-dot layers 241. Each quantum-dot layer 241 contains quantum dots.

The quantum-dot layers 241 may be made of any material, but are preferably made of a III-V compound semiconductor.

Quantum dots 411 are preferably made of a semiconductor material that has lower band gap energy than does an intermediate layer 415.

The quantum-dot layers 241 are preferably made of any of, for example, GaAsₓSb₁₋ₓ, AlSb, InAsₓSb₁₋ₓ, GaₓIn₁₋ₓSb, AlSbₓAs₁₋ₓ, AlAs_{z}Sb_{1-z}, InₓGa₁₋ₓAs, AlₓGa₁₋ₓAs, Al_{y}Ga_{1-y}As_{z}Sb_{1-z}, InₓGa₁₋ₓP, (Al_{y}Ga_{1-y})_{z}In_{1-z}P, GaAsₓP₁₋ₓ, Ga_{y}In_{1-y}As_{z}P_{1-z}, and InₓAl₁₋ₓAs, where 0≤x≤1, 0≤y≤1, and 0≤z≤1 in these materials and throughout the rest of the specification. Alternatively, the quantum-dot layers 241 may be made of a mixed crystal of any of these materials.

As another alternative, the quantum-dot layers 241 may be made of a compound semiconductor of a Group V semiconductor material and either a Group IV semiconductor or a Group III semiconductor material and may be made of a compound semiconductor of a Group H semiconductor material and a Group VI semiconductor material, as can be found in the periodic table. Alternatively, the quantum-dot layers 241 may be made of a mixed crystal of any of these compound semiconductors. As a further alternative, the quantum-dot layers 241 may be made of a chalcopyrite-based material or a non-chalcopyrite-based semiconductor material.

The photoelectric conversion layer 24 may be either an i-type semiconductor layer or a semiconductor layer containing a p-type impurity or a n-type impurity.

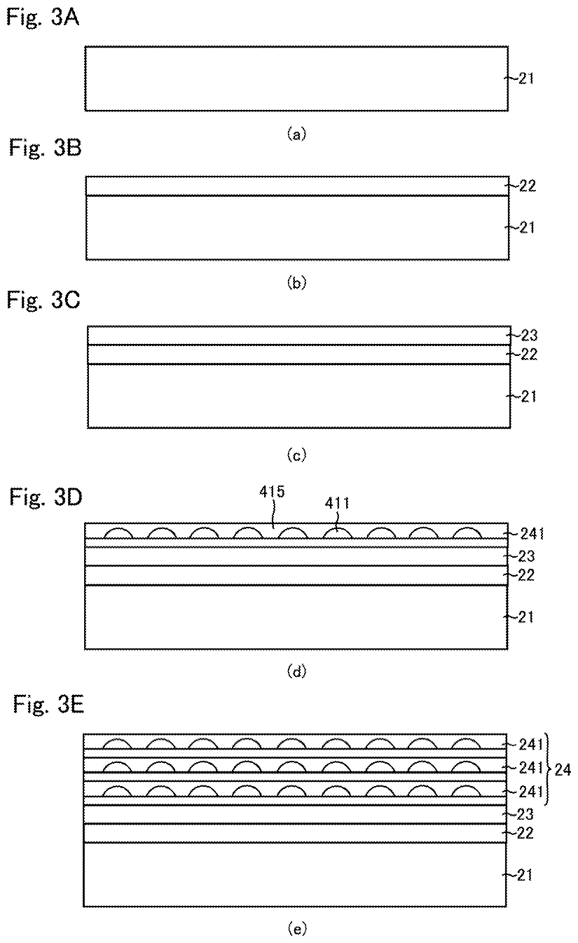

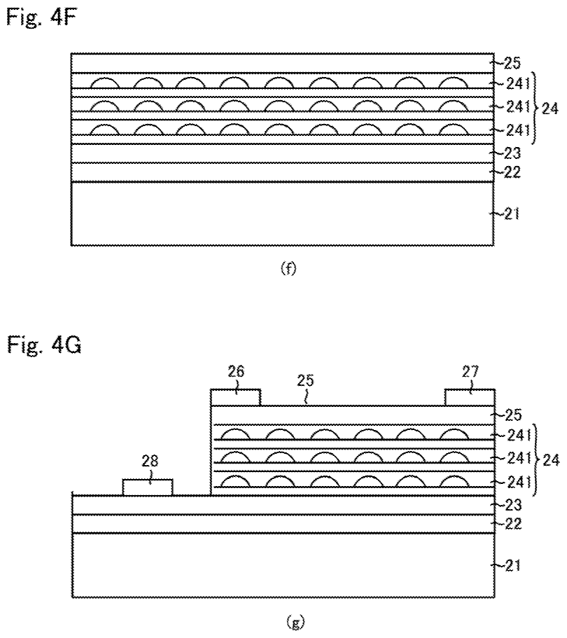

FIGS. 3 and 4 are first and second manufacturing process diagrams respectively of a method of manufacturing the quantum-dot infrared photodetector 20 shown in FIG. 2.

Referring to FIG. 3, upon starting the manufacture of the quantum-dot infrared photodetector 20, the semiconductor substrate 21, which is made of semi-insulating GaAs, is placed inside a molecular beam epitaxy (MBE) device (step (a) in FIG. 3).

The buffer layer 22 is then formed on the semiconductor substrate 21 by MBE (step (b) in FIG. 3). For example, a 200-nm thick GaAs layer is formed here as the buffer layer 22. The presence of the buffer layer 22 enables improving the crystallinity of the photoelectric conversion layer 24 to be formed on the buffer layer 22. The photoelectric conversion layer 24 hence guarantees a high photoreception efficiency in the resultant infrared light detection element.

Subsequent to step (b), the n-type semiconductor layer 23 is formed on the buffer layer 22 by MBE (step (c) in FIG. 3). For example, a 500-nm thick n-GaAs layer is formed here as the n-type semiconductor layer 23.

Subsequently, one of the quantum-dot layers 241 including the quantum dots 411 and the intermediate layer 415 is formed on the n-type semiconductor layer 23 by MBE (step (d) in FIG. 3).

The quantum dots 411 are formed here by a technique called Stranski-Krastanov (S-K) growth.

More specifically, a GaAs (crystal) layer is grown as the intermediate layer 415. After that, an Al_{0.4}Ga_{0.6}As crystal layer is grown as an underlayer 412 (barrier layer; not shown) for the quantum dots 411, and the quantum dots 411 of InAs are formed by self-assembly mechanism. An Al_{0.4}Ga_{0.6}As crystal layer is then grown as a partial capping layer 414 (not shown) to cap the quantum dots 411. Thereafter, a GaAs crystal layer is grown as an intermediate layer, which completes the formation of the quantum-dot layer 241.

Step (d) is repeated, for example, 10 times, to form on the n-type semiconductor layer 23 the photoelectric conversion layer 24 including a stack of the quantum-dot layers 241 (step (e) in FIG. 3).

The thickness of the intermediate layer 415 is, for example, 40 nm, which is sufficiently large in comparison with the thickness of the barrier layers (underlayer 412 and partial capping layer 414). The thickness of the barrier layers (underlayer 412 and partial capping layer 414) is, for example, 1 nm because the barrier layers need to be so thin that the excited carriers can tunnel through to the intermediate layer 415.

After step (e) in FIG. 3, the n-type semiconductor layer 25 is formed on the photoelectric conversion layer 24 by MBE (step (f) in FIG. 4). For example, a n-GaAs crystal layer is grown here to a thickness of 200 nm as the n-type semiconductor layer 25. A n-i-n structure is hence formed.

Subsequently, the laminate is removed from the MBE device and subjected to photolithography and wet etching to partially remove the photoelectric conversion layer 24 and the n-type semiconductor layer 25. The electrodes 26 and 27 are then formed on the n-type semiconductor layer 25, and the electrode 28 is formed on the n-type semiconductor layer 23, which completes the manufacture of the quantum-dot infrared photodetector 20 (step (g) in FIG. 4).

A description is now given of how to calculate the temperature of the measurement object 30. The radiation spectrum of a measurement object 30 agrees generally with the Planck equation given below:

$$\begin{matrix}[ Math . 1 ] & \\ I ( λ ) = \frac{2 {hc}^{2}}{{λ}^{s}} \frac{1}{exp [ \frac{hc}{λ {k}_{B} T} ] - 1} & ( 1 )\end{matrix}$$

where equation (1) λ is a wavelength, h is the Planck's constant, k_{B} is the Boltzmann's constant, c is the speed of light, and T is the absolute temperature of the measurement object 30.

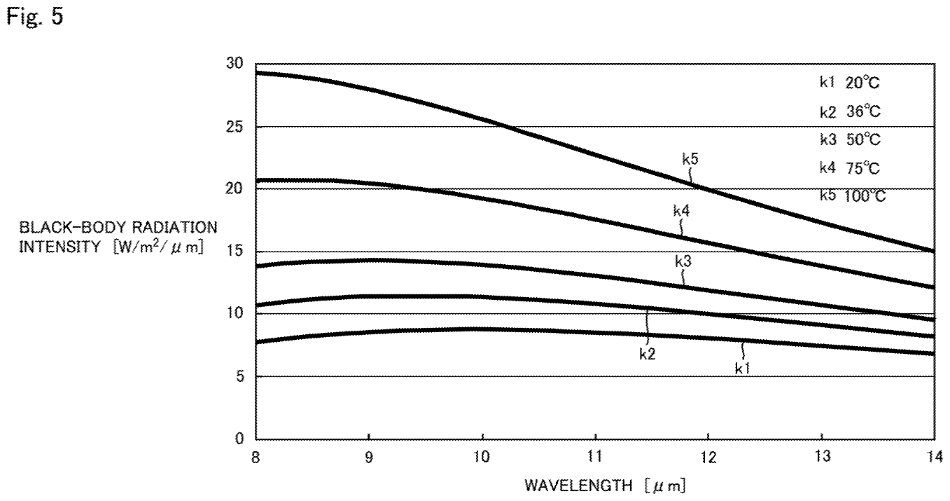

FIG. 5 is a graph representing a relationship between black-body radiation intensity and wavelength. In FIG. 5, the vertical axis represents black-body radiation intensity, and the horizontal axis represents wavelength. Curved lines k1 to k5 represent respective relationships between black-body radiation intensity and wavelength when the temperature of the measurement object 30 is 20° C., 36° C., 50° C., 75° C., and 100° C. FIG. 5 shows that the wavelength dependency of black-body radiation intensity varies with the temperature of the measurement object 30 and also that the peak wavelength of infrared light at which black-body radiation intensity assumes a maximum value can vary.

The detection value that can be detected by the detection unit 1 is theoretically a product of a radiation spectrum I(λ) multiplied by a solid angle α in which heat radiation is detectable (a detectable proportion of the black-body radiation intensity, alternatively referred to as a detection proportion), a transmittance τ(λ) through air, the emissivity ε(λ) of the measurement object 30, and a detection sensitivity A(λ) of the detection unit 1, integrated over the detection wavelength range. It is the detection sensitivity A(λ) of the detection unit 1 and the detection wavelength range that are dependent on the detection unit 1.

In the detection unit 1, the detection value D_{R} of the reference element 12 is given by the following formula:

[Math. 2]

D_{R}=α∫_{R}_{₁}^{R}^{₂}ε(λ)×τ(λ)×A_{R}(λ)×I(λ)dλ (2)

When the reference element 12 is a thermal infrared sensor, the detection wavelength range is dependent on the transmittance because the high-transmittance wavelength range through air is narrower than the detectable wavelength range for the thermal infrared sensor.

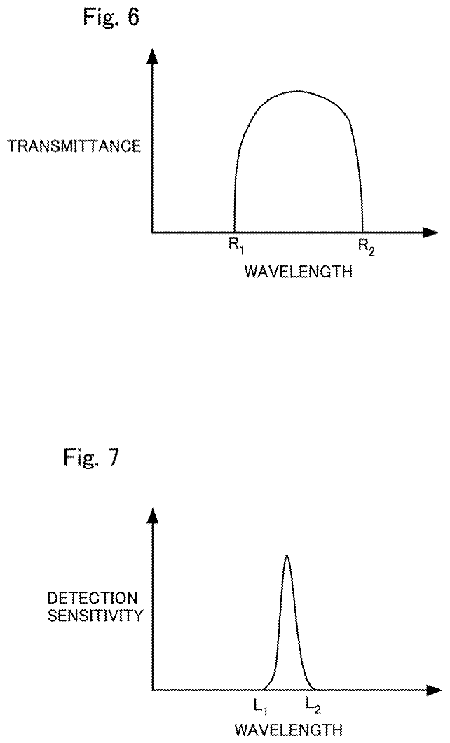

FIG. 6 is a diagram representing a relationship between transmittance and wavelength. In FIG. 6, the vertical axis represents transmittance, and the horizontal axis represents wavelength. Referring to FIG. 6, transmittance is high in the range of wavelengths from R₁ to R₂. When the reference element 12 is a thermal infrared sensor, the detection wavelength range (first wavelength range) is the wavelength range from R₁ to R₂ shown in FIG. 6 because the reference element 12 has a broad detection sensitivity. Transmittance in air is dictated by absorption by gases (primarily water vapor) in the air. When there is a lens or like optical element before the detection unit 1, the radiation spectrum I(λ) is additionally multiplied by the transmittance of these optical elements. Therefore, when there is an optical element on the infrared-light-incident side of the reference element 12, the detection wavelength range (first wavelength range) of the reference element 12 is the transmission wavelength range of the optical element.

The detection value D_{D} of the detection element 11 is a sum of an optical signal component D_{L} and an amount of change (thermal signal component) D_{N} of a thermal signal caused by a rise in the temperature of the detection element 11 under infrared light radiation and is given by the following formula:

[Math. 3]

D_{D}=D_{L}+D_{N} (3)

The optical signal component D_{L} in equation (3) is given by the following formula:

[Math. 4]

D_{L}=α∫_{L}_{₁}^{L}^{₂}ε(λ)×τ(λ)×A_{L}(λ)×I(λ)dλ (4)

The amount of change D_{N} of the thermal signal in equation (3) is given by the following formula:

[Math. 5]

D_{N}=α∫_{N}_{₁}^{N}^{₂}ε(λ)×τ(λ)×A_{N}(λ)×I(λ)dλ (5)

FIG. 7 is a diagram representing a relationship between detection sensitivity and wavelength. In FIG. 7, the vertical axis represents detection sensitivity, and the horizontal axis represents wavelength. The wavelength range for which the detection element 11 can generate an optical signal is the wavelength range from L₁ to L₂ shown in FIG. 7 (second wavelength range). This wavelength range (L₁ to L₂) overlaps the wavelength range (R₁ to R₂) shown in FIG. 6.

The wavelength range for which the detection element 11 can generate an optical signal is characteristic to the detection element 11. A quantum-dot or quantum-well detection element can generate an optical signal for a particularly narrow wavelength range.

Meanwhile, the thermal signal of the detection element 11 is not dependent on the detection sensitivity of the detection element 11. The wavelength range N₁ to N₂ for which the detection element 11 can generate a thermal signal is the wavelength range R₁ to R₂ shown in FIG. 6. In other words, the amount of change D_{N} of the thermal signal is given by the following formula:

[Math. 6]

D_{N}=α∫_{R}_{₁}^{R}^{₂}ε(λ)×τ(λ)×A_{N}(λ)×I(λ)dλ (6)

The detection value D_{R} of the reference element 12 in equation (2) only differs from the amount of change D_{N} of the thermal signal in equation (6) in detection sensitivities A_{R}(λ) and A_{N}(λ), which shows that the amount of change D_{N} of the thermal signal has a correlation with the detection value D_{R} of the reference element 12. It is therefore possible to calculate the amount of change D_{N} of the thermal signal from the detection value D_{R} of the reference element 12. The optical signal component D_{L} can be hence calculated by plugging the detection value D_{D} of the detection element 11 and the amount of change D_{N} of the thermal signal into equation (3).

It is also possible to calculate an integrated radiation illuminance over the wavelength range shown in FIG. 6 from the detection value D_{R} of the reference element 12. In other words, the reference element 12 can be treated as a detection element that exhibits detection sensitivity over the wavelength range shown in FIG. 6.

A description is given of a technique for calculating the temperature of the measurement object 30. The transmittance τ(λ), emissivity ε(λ), and a detection sensitivity A_{N}(λ) are typically considered not dependent on wavelength (constant over the detection wavelength range) in calculation. The wavelength range shown in FIG. 7 lies within the wavelength range shown in FIG. 6. The transmittance τ(λ) and emissivity ε(λ) in the wavelength range shown in FIG. 6 and the wavelength range shown in FIG. 7 are therefore further approximated as being equal. In addition, a detection proportion α can also be assumed to be equal in the detection element 11 and the reference element 12.

Equations (2), (4), and (6) described above give the following equations (7), (8), and (9) respectively:

[Math. 7]

D_{R}=α×ε×τ×A_{R}∫_{R}_{₁}^{R}^{₂}I(λ)dλ (7)

[Math. 8]

D_{L}=α×ε×τ×A_{L}∫_{L}_{₁}^{L}^{₂}I(λ)dλ (8)

[Math. 9]

D_{N}=α×ε×τ×Δ_{N}∫_{R}_{₁}^{R}^{₂}I(λ)dλ=A_{N}×D_{R}/A_{R} (9)

Plugging equations (8) and (9) into equation (3), an output D_{D} of the detection element 11 is given by the following formula:

$$\begin{matrix}[ Math . 10 ] & \\ {D}_{D} = α \times ɛ \times τ \times {A}_{L} {\int }_{{L}_{1}}^{{L}_{2}} I ( λ ) dλ + {A}_{N} \times \frac{{D}_{R}}{{A}_{R}} & ( 10 )\end{matrix}$$

The ratio of the detection value D_{D} of the detection element 11 and the detection value D_{R} of the reference element 12 is given by the following formula:

$$\begin{matrix}[ Math . 11 ] & \\ \frac{{D}_{D}}{{D}_{R}} = \frac{{A}_{L} {\int }_{{L}_{1}}^{{L}_{2}} I ( λ ) dλ}{{A}_{R} {\int }_{{R}_{1}}^{{R}_{2}} I ( λ ) dλ} + \frac{{A}_{N}}{{A}_{R}} & ( 11 )\end{matrix}$$

Hence, the ratio of the detection value D_{D} and the detection value D_{R} has a value not dependent on α×ελτ.

The detection sensitivities A_{L} and A_{N} of the detection element 11 and the detection sensitivity A_{R} of the reference element 12 are known because they can be measured in advance. Therefore, a temperature T of the measurement object 30 included in the radiation spectrum I(λ) represented by equation (1) can be calculated by plugging the detection sensitivities A_{L}, A_{N}, and A_{R} and a ratio D_{D}/D_{R} of the detection value D_{D} of the detection element 11 and the detection value D_{R} of the reference element 12 into equation (11).

The temperature of the measurement object 30 can be alternatively calculated by evaluating the right-hand side of equation (11) using a different temperature and finding a temperature that matches the left-hand side of equation (11).

The first term in the right-hand side can be calculated using equation (11). This numerator represents an optical signal component and is therefore free from thermal effect. Accordingly, the effect of the amount of change D_{N} of a thermal signal caused by a rise in the temperature of the detection element 11 under infrared light radiation is removed by calculating the temperature T of the measurement object 30 using equation (11). Additionally, by using D_{R} that corresponds to a thermal signal component D_{N} detected by the detection element 11, the temperature T of the measurement object 30 can be calculated.

The temperature calculating technique described above may be considered as an application, to two wavelength ranges with an overlapping detection wavelength range, of a so-called “two-color method” whereby temperature is calculated from a ratio of detection values for different wavelength ranges.

However, a common two-color method only deals with two non-overlapping wavelength ranges and for this reason, will likely to lead to error if the detection values of the reference element and the detection element are calculated on an assumption that the reference element and the detection element have an equal emissivity and transmittance.

Meanwhile, in the above-described technique, the detection wavelength range of the detection element 11 lies within the detection wavelength range of the reference element 12 (the detection wavelength range of the detection element 11 partially overlaps the detection wavelength range of the reference element 12). The technique hence does not lead to error even if it is assumed that the reference element and the detection element have an equal emissivity and transmittance. Accordingly, the temperature of the measurement object 30 can be calculated with less error by using the above-described technique.

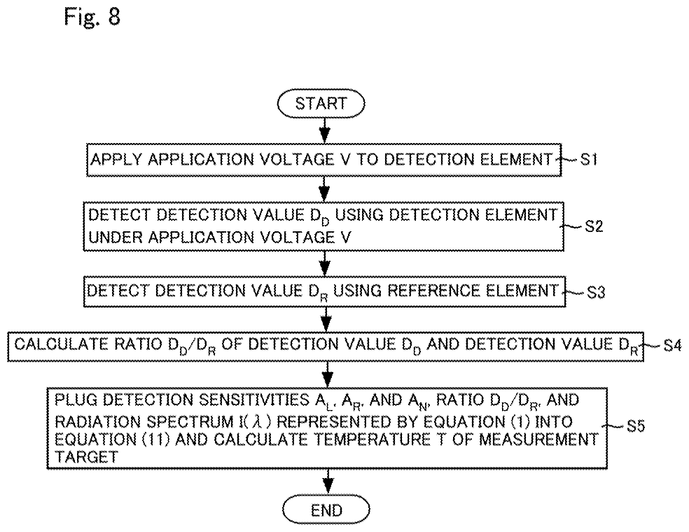

FIG. 8 is a flow chart representing an infrared photodetection process in accordance with Embodiment 1. Referring to FIG. 8, upon starting the infrared photodetection process, the operation unit 2 applies the application voltage V to the detection element 11 (step S1). When the detection wavelength range needs to be broader here than in a case where the application voltage is constant, an application voltage V=V0+ΔV sin(2πt/T_{S}) is applied to the detection element 11, to achieve the broader detection wavelength range.

Under the application voltage V, the detection element 11 detects the detection value D_{D} (step S2) and outputs the detected detection value D_{D} to the operation unit 2. The operation unit 2 outputs the detection value D_{D} received from the detection element 11 to the calculation section 3.

The reference element 12 detects the detection value D_{R} (step S3) and outputs the detected detection value D_{R} to the operation unit 2. The operation unit 2 outputs the detection value D_{R} received from the reference element 12 to the calculation section 3.

The calculation section 3 receives the detection values D_{D} and D_{R} from the operation unit 2 and calculates the ratio D_{D}/D_{R} of the detection value D_{D} and the detection value D_{R} from the received detection values D_{D} and D_{R} (step S4).

The calculation section 3 then plugs the known detection sensitivities A_{L}, A_{R}, and A_{N}, the ratio D_{D}/D_{R}, and the radiation spectrum I(λ) represented by equation (1) into equation (11) to calculate the temperature T of the measurement object 30 (step S5), which completes the infrared photodetection process.

The flow chart shows an example where the detection value D_{D} and the detection value D_{R} are detected one after the other. Alternatively, the detection value D_{D} and the detection value D_{R} may be detected in parallel.

### Temperature Calculation Precision

A description is now given of the precision of the calculated temperature of the measurement object 30. In equation (11), it is the ratio of integrated values of a black-body radiation brightness spectrum that is dependent on temperature.

The detectable wavelength range for the reference element 12 shown in FIG. 6 may be determined from transmittance in the atmospheric window. An atmospheric window is a range of wavelengths over which there is little influence from the atmosphere and the light transmittance is high. In the mid-infrared to far-infrared wavelength range, there is an atmospheric window from 3.4 to 4.2 μm, from 4.4 to 5.5 μm, and from 8 to 14 μm. The atmospheric window from 8 to 14 μm is used here.

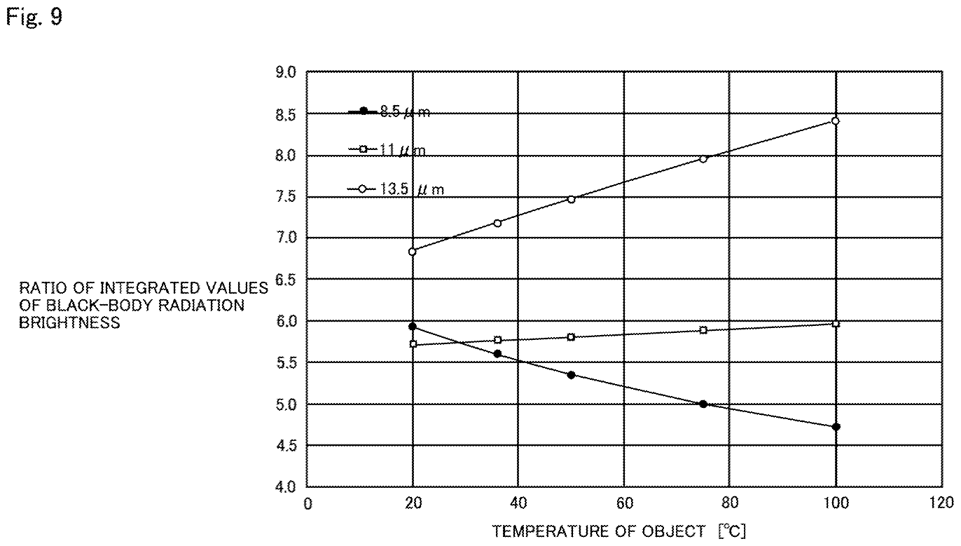

FIG. 9 is a diagram representing a relationship between the ratio of integrated values of black-body radiation brightness and the temperature of an object. In FIG. 9, the vertical axis represents the ratio of integrated values of black-body radiation brightness, and the horizontal axis represents the temperature of an object. A black circle indicates a relationship between the ratio of integrated values of black-body radiation brightness and the temperature of an object when the detection wavelength range of the detection element 11 has a central wavelength of 8.5 μm. A white square indicates a relationship between the ratio of integrated values of black-body radiation brightness and the temperature of an object when the detection wavelength range of the detection element 11 has a central wavelength of 11 μm. A white circle indicates a relationship between the ratio of integrated values of black-body radiation brightness and the temperature of an object when the detection wavelength range of the detection element 11 has a central wavelength of 13.5 μm.

The ratio of integrated values of a black-body radiation brightness spectrum are plotted in FIG. 9 under the conditions that the detectable wavelength range for the detection element 11 shown in FIG. 7 has a width of 1 μm and a central wavelength of 8.5 μm, 11 μm, or 13.5 μm.

FIG. 9 shows that changes in the temperature of the measurement object 30 are detected with high sensitivity when the detectable wavelength range for the detection element 11 lies near an end, rather than in the center, of the detectable wavelength range for the reference element 12.

For instance, the ratio of integrated values of black-body radiation brightness grows with a rise in temperature for the detection value, 8 to 14 μm, detected by the reference element 12 rather than for the detection value detected by the detection element 11 for a central wavelength of 13.5 μm and a width of 1 μm (in other words, 13 μm to 14 μm) because there occurs an increase in black-body radiation brightness in 8 to 14 μm due to a rise in the temperature of the measurement object 30 (see white circles in FIG. 9).

When the detection wavelength range of the detection element 11 is from 8 to 9 μm, almost the opposite is true (see black circles in FIG. 9).

When the detection wavelength range of the detection element 11 is in the center of the detection wavelength range of the reference element 12, the temperature dependency of black-body radiation brightness appears equally in both elements. The temperature dependency of the ratio of integrated values of black-body radiation brightness is therefore reduced.

The ratio of integrated values of black-body radiation brightness changes more with a change in the temperature of the measurement object 30 when the temperature of the measurement object 30 is lower. This is especially evident when the detection wavelength range of the detection element 11 is from 8 to 9 μm. This is, as can be understood from FIG. 5, an influence of the central wavelength of black-body radiation brightness lying toward the range greater than or equal to 8 μm when the temperature is at or below 75° C.

Accordingly, when the detectable temperature range is as relatively low as, for example, 20 to 40° C., 8.5 μm is preferred to the central wavelength of 13.5 μm.

When the detection wavelength range of the detection element 11 is from 13 to 14 μm, there is no influence of this. Therefore, the ratio of integrated values of black-body radiation brightness changes substantially linearly with the temperature of the measurement object 30, which facilitates analysis.

The detection wavelength ranges of the detection element 11 and the reference element 12 have been so far described as being symmetric with respect to the central wavelength. Alternatively, the detection wavelength ranges may be asymmetric.

In Embodiment 1, the operations of the calculation section 3 may be implemented using software. In such a case, the calculation section 3 includes: an ALU (arithmetic logic unit); a CPU (central processing unit) including a computation-enabled computation section such as an adder or a multiplier; a ROM (read-only memory); and a RAM (random access memory).

The ROM contains a program Prog_A including: step S1-1 where the detection values D_{D} and D_{R} are received from the detection element 11 and the reference element 12 respectively; and steps S4 and S5 shown in FIG. 8. The ROM also contains the known detection sensitivities A_{L}, A_{R}, and A_{N}. The RAM temporarily stores the calculated ratio D_{D}/D_{R}.

The CPU retrieves the program Prog_A from the ROM and executes the program Prog_A to calculate the temperature T of the measurement object 30 using the above-described technique. In such a case, the CPU sequentially executes steps S1-1, S4, and S5.

The CPU, which calculates the ratio D_{D}/D_{R} and the temperature T of the measurement object 30, constitutes at least a part of a calculation means. The CPU, which receives the detection values D_{D} and D_{R}, constitutes at least a part of a reception means.

The program Prog_A may be contained in a storage medium (e.g., CD or DVD) for distribution. In such a case, the computer (CPU) retrieves the program Prog_A from the storage medium and executes the program Prog_A to calculate the temperature of the measurement object 30 using the above-described technique. Accordingly, the CD, DVD, and other like storage media containing the program Prog_A are computer-(CPU-)readable storage media containing the program Prog_A.

### Embodiment 2

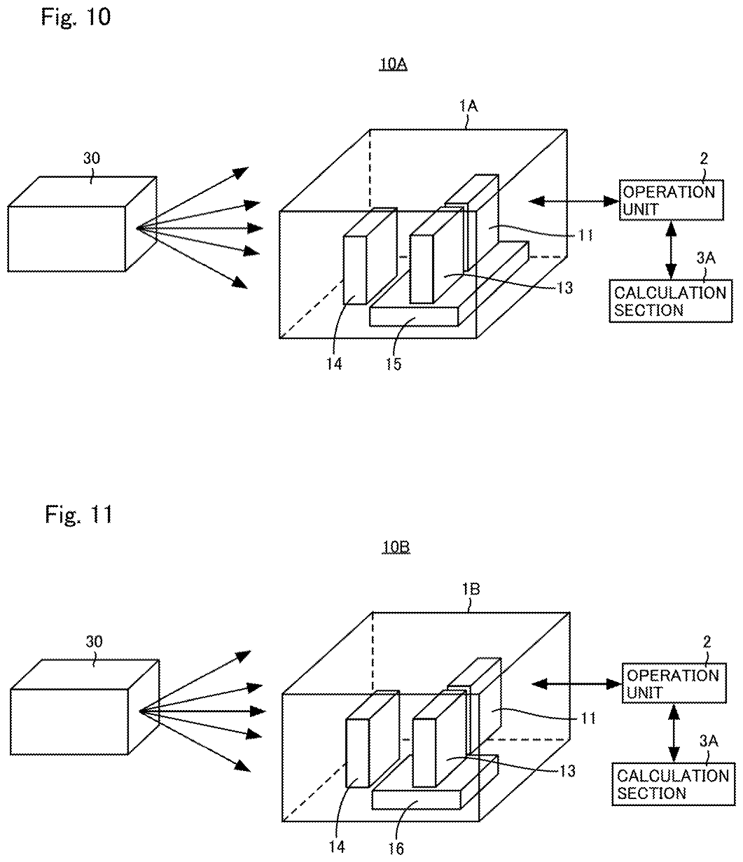

FIG. 10 is a schematic view of an infrared photodetection device in accordance with Embodiment 2. Referring to FIG. 10, an infrared photodetection device 10A in accordance with Embodiment 2 includes a detection unit 1A and a calculation section 3A in place of the detection unit 1 and the calculation section 3 respectively in the infrared photodetection device 10 shown in FIG. 1. The infrared photodetection device 10A is otherwise identical to the infrared photodetection device 10.

The detection unit 1A includes a detection element 13 in place of the reference element 12 in the detection unit 1 shown in FIG. 1 and further includes a reflector 14 and a heat conductor 15. The detection unit 1A is otherwise identical to the detection unit 1.

The detection element 13 includes the same detection element as the detection element 11. The reflector 14 is disposed on the infrared-light-incident side of the detection element 13 so as to face the detection element 13. The reflector 14 reflects infrared light incident on the detection element 13 and is preferably highly reflective to infrared light. The detection elements 11 and 13 are disposed on the heat conductor 15 in contact with the heat conductor 15. The heat conductor 15 transfers a thermal signal component detected by the detection element 11 to the detection element 13. Therefore, the detection element 13 detects D_{R} corresponding to the amount of change D_{N} of a thermal signal caused by a rise in the temperature of the detection element 11 under infrared light radiation described above and outputs a detected amount of change D_{R} to the operation unit 2. In other words, the detection element 13 detects a thermal signal component (D_{R}), but not an optical signal component. More particularly, the detection element 13 detects the thermal signal component detected by the detection element 11, but not the optical signal component detected by the detection element 11. If the detection element 13 is capable of detection over a sufficiently broad wavelength range as a thermal signal component here, the second wavelength range is practically the wavelength range (A) of the infrared light radiating from an object and being actually incident on the detection element 13.

The calculation section 3A calculates the ratio D_{D}/D_{R} of the detection value D_{D} of the detection element 11 and the detection value D_{R} of the detection element 13. The calculation section 3A then calculates the temperature T of the measurement object 30 using equation (11) and the technique described in Embodiment 1.

In the infrared photodetection device 10A, the heat conductor 15 renders the detection value D_{R} of the detection element 13 equal to the amount of change D_{N} of a thermal signal caused by a rise in the temperature of the detection element 11 under infrared light radiation. The detection element 13 thus enables accurate detection of the amount of change D_{N} of a thermal signal caused by a rise in the temperature of the detection element 11.

FIG. 11 is a schematic view of another infrared photodetection device in accordance with Embodiment 2. The infrared photodetection device in accordance with Embodiment 2 may be an infrared photodetection device 10B shown in FIG. 11. Referring to FIG. 11, the infrared photodetection device 10B includes a detection unit 1B in place of the detection unit 1A in the infrared photodetection device 10A shown in FIG. 10 and is otherwise identical to the infrared photodetection device 10A.

The detection unit 1B includes an absorber 16 in place of the heat conductor 15 in the detection unit 1A shown in FIG. 10 and is otherwise identical to the detection unit 1A.

In the detection unit 1B, the detection element 13 is disposed on the absorber 16 in contact with the absorber 16. The absorber 16 absorbs the light radiating from the measurement object 30 over a broader range (e.g., 8 to 14 μm) than the detectable wavelength range for the detection element 13 to transfer the heat produced by the light to the detection element 13.

Without the absorber 16, the environmental temperature of the detection element 13 would rise less under infrared light having wavelengths from 8 to 14 μm than the environmental temperature of the detection element 11 by as much as the reflected infrared light. That could render the detection element 13 less sensitive to the thermal component. The absorber 16 is preferably adjusted in such a manner that the environmental temperature of the detection element 13 can rise as much as the environmental temperature of the detection element 11. This adjustment renders the detection value D_{R} of the detection element 13 equal to the amount of change D_{N} of the thermal signal of the detection element 11.

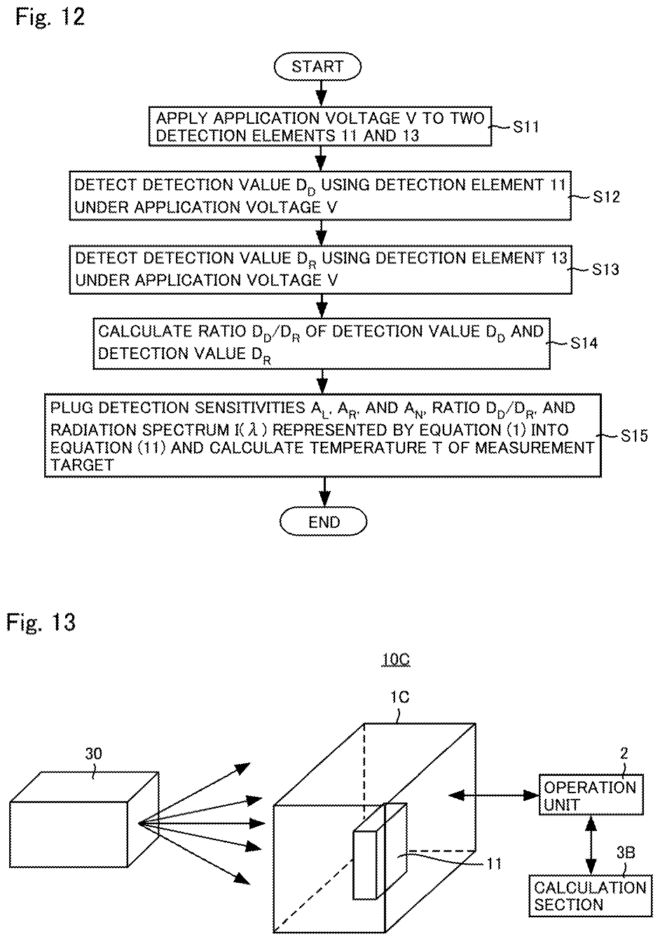

FIG. 12 is a flow chart representing an infrared photodetection process in accordance with Embodiment 2.

Referring to FIG. 12, upon starting the infrared photodetection process, the operation unit 2 applies the application voltage V to the detection elements 11 and 13 (step S11). When the detection wavelength range needs to be broader here than in a case where the application voltage is constant, such an application voltage V that the broader detection wavelength range can be achieved is applied to the detection elements 11 and 13.

Under the application voltage V, the detection element 11 detects the detection value D_{D} (step S12) and outputs the detected detection value D_{D} to the operation unit 2. The operation unit 2 outputs the detection value D_{D} received from the detection element 11 to the calculation section 3A.

The detection element 13 detects the detection value D_{R} under the application voltage V (step S13) and outputs the detected detection value D_{R} to the operation unit 2. The operation unit 2 outputs the detection value D_{R} received from the detection element 13 to the calculation section 3A.

The calculation section 3A receives the detection values D_{D} and D_{R} from the operation unit 2 and calculates the ratio D_{D}/D_{R} of the detection value D_{D} and the detection value D_{R} from the received detection values D_{D} and D_{R} (step S14).

The calculation section 3A then plugs the known detection sensitivities A_{L}, A_{R}, and A_{N}, the ratio D_{D}/D_{R}, and the radiation spectrum I(λ) represented by equation (1) into equation (11) to calculate the temperature T of the measurement object 30 (step S15), which completes the infrared photodetection process.

The flow chart shows an example where the detection value D_{D} and the detection value D_{R} are detected one after the other. Alternatively, the detection value D_{D} and the detection value D_{R} may be detected in parallel.

A common two-color method detects infrared light using two detection wavelengths and, for this reason, needs two different detection elements and/or two different wavelength filters. On the other hand, Embodiment 2 needs only one type of detection element, thereby reducing device cost and development cost.

Besides, Embodiment 2 additionally achieves the various effects described in Embodiment 1.

In Embodiment 2, the operations of the calculation section 3A may be implemented using software. In such a case, the calculation section 3A includes a CPU (including a computation section), a ROM, and a RAM.

The ROM contains a program Prog_B including: step S1-1 where the detection values D_{D} and D_{R} are received from the detection element 11 and the detection element 13 respectively; and steps S14 and S15 shown in FIG. 12. The ROM also contains the known detection sensitivities A_{L}, A_{R}, and A_{N}. The RAM temporarily stores the calculated ratio D_{D}/D_{R}.

The CPU retrieves the program Prog_B from the ROM and executes the program Prog_B to calculate the temperature T of the measurement object 30 using the above-described technique. In such a case, the CPU sequentially executes steps S1-1, S14, and S15.

The CPU, which calculates the ratio D_{D}/D_{R} and the temperature T of the measurement object 30, constitutes at least a part of a calculation means. The CPU, which receives the detection values D_{D} and D_{R}, constitutes at least a part of a reception means.

The program Prog_B may be contained in a storage medium (e.g., CD or DVD) for distribution. In such a case, the computer (CPU) retrieves the program Prog_B from the storage medium and executes the program Prog_B to calculate the temperature of the measurement object 30 using the above-described technique. Accordingly, the CD, DVD, and other like storage media containing the program Prog_B are computer-(CPU-)readable storage media containing the program Prog_B.

In Embodiment 2, when the detection element 13 exhibits polarization-dependent characteristics in light absorption, a polarizer is used as the reflector 14. The polarized light to be detected is adjusted using the polarizer in such a manner that no optical signal component can be detected.

The description of Embodiment 1 applies to Embodiment 2 unless otherwise mentioned explicitly.

### Embodiment 3

FIG. 13 is a schematic view of an infrared photodetection device in accordance with Embodiment 3. Referring to FIG. 13, an infrared photodetection device IOC in accordance with Embodiment 3 includes a detection unit 1C and a calculation section 3B in place of the detection unit 1 and the calculation section 3 respectively in the infrared photodetection device 10 shown in FIG. 1 and is otherwise identical to the infrared photodetection device 10.

The detection unit 1C has the same structure as the detection unit 1 shown in FIG. 1, except that the detection unit 1C includes no reference element 12.

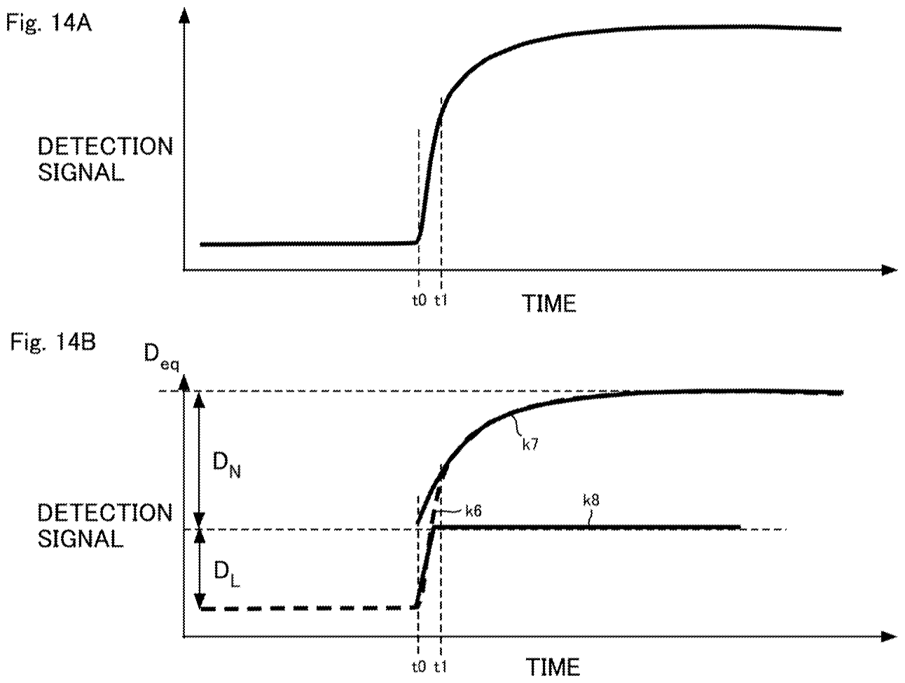

FIG. 14 is a set of conceptual drawings illustrating a time response of a detection signal. In FIG. 14, the vertical axis represents a detection signal, and the horizontal axis represents time. FIG. 14(a) represents a time response of the detection value D_{D} when infrared light incidents on the detection element 11 at time t0. In FIG. 14(b), curved line k6 represents a time response of the detection value D) shown in FIG. 14(a), curved line k7 represents a time response of a thermal signal component, and curved line k8 represents a time response of an optical signal component.

Referring to FIG. 14(a), the time response of the detection value D_{D} abruptly increases at time t0, slows down at time t1 and onwards, and eventually levels off at an equilibrium value Deq. This is because the optical signal component is primarily detected from time t0 to time t1 and the thermal signal component is primarily detected from time t1 and onwards.

FIG. 14(b) illustrates a theoretical model of the optical and thermal signal components. The time response of the optical signal component is inherently similar to a step function (see curved line k8). The time response of the thermal signal component changes like an exponential function (see curved line k7).

Because the equilibrium value of the optical signal component is not distinguishable in the detection signal, analysis is done using the following formula:

[Math. 12]

D_{D}=D_{N}(1−exp[−(t−t₀)/τ])+D_{L} (12)

In equation (12), r is a heat diffusion time.

The calculation section 3B calculates D_{N} and D_{L} by fitting from the detection signal at time t1 and onwards using equation (12), with time t1 being 1 to 2 seconds, which is sufficiently longer than the time response of the optical signal component and shorter than the time response of the thermal signal component.

This technique enables distinguishing between the optical signal component and the thermal signal component for separate detection thereof by using the detection element 11. If the detection element 11 is capable of detection over a sufficiently broad wavelength range, the second wavelength range is practically the wavelength range (A) of the infrared light radiating from an object and being actually incident on the detection element 11.

The calculation section 3B then calculates a ratio D_{D}/D_{N} of D_{D} and D_{N} by either plugging calculated D_{N} and D_{L} into equation (3) and thus calculating D_{D} or using the value of D_{D} in the equilibrium state.

Accordingly, the calculation section 3B plugs the known detection sensitivities A_{L}, A_{R}, and A_{N}, the ratio D_{D}/D_{N}, and the radiation spectrum I(λ) represented by equation (1) into an equation obtained from equation (11) by replacing D_{D}/D_{R} with DI/D_{N} therein, to calculate the temperature T of the measurement object 30.

Precision increases with fewer parameters being subjected to fitting. For instance, because the heat diffusion time is dictated by the detection unit, the surrounding structure, and the environmental temperature, data may be stored beforehand for each environmental temperature, so that values may be specified in based on the results of separate measurement of the environmental temperature. Meanwhile, D_{N} and D_{L} are subjected to fitting every time because D_{N} and D_{L} vary from one detection to the other.

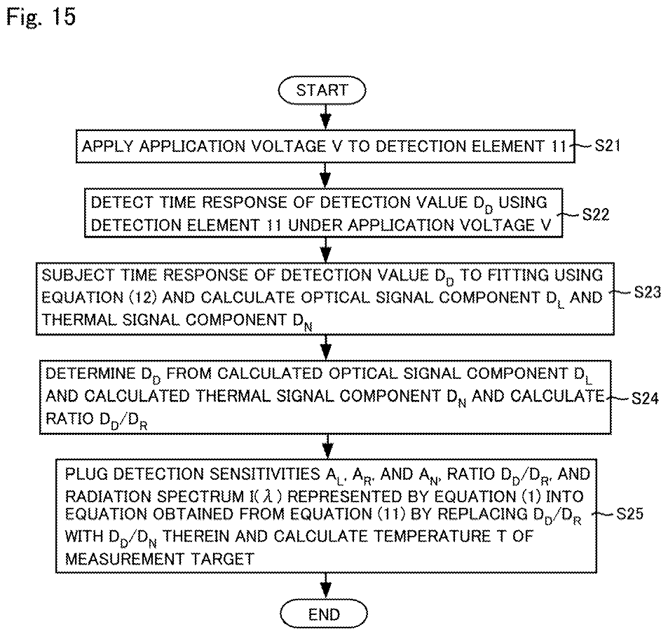

FIG. 15 is a flow chart representing an infrared photodetection process in accordance with Embodiment 3.

Referring to FIG. 15, upon starting the infrared photodetection process, the operation unit 2 applies the application voltage V to the detection element 11 to set the detection wavelength range of the detection element 11 to the detection wavelength range shown in FIG. 7 (step S21).

The detection element 11 then detects a time response of the detection value D_{D} under the application voltage V (step S22) and outputs the detected time response of the detection value D_{D} to the operation unit 2. The operation unit 2 outputs the time response of the detection value D_{D} received from the detection element 11 to the calculation section 3B.

The calculation section 3B receives the time response of the detection value D_{D} from the operation unit 2, subjects the received time response of the detection value D_{D} to fitting using equation (12), and calculates the optical signal component D_{L} and the thermal signal component D_{N} (step S23).

The calculation section 3B then determines D_{D} from the calculated optical signal component D_{L} and the calculated thermal signal component D_{N} (see equation (3)) and calculates the ratio D_{D}/D_{N} (step S24).

Accordingly, the calculation section 3B plugs the known detection sensitivities A_{L}, A_{R}, and A_{N}, the ratio D_{D}/D_{N}, and the radiation spectrum I(λ) represented by equation (1) into an equation obtained from equation (11) by replacing D_{D}/D_{R} with D_{D}/D_{N} therein, to calculate the temperature T of the measurement object 30 (step S25), which completes the infrared photodetection process.

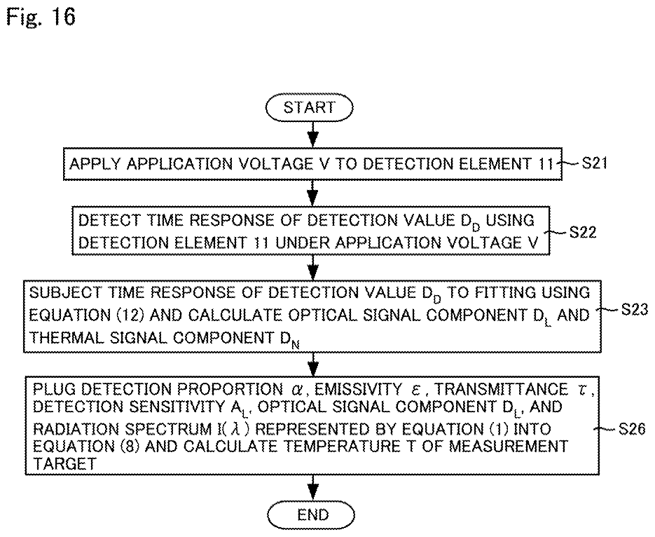

FIG. 16 is another flow chart representing infrared photodetection process in accordance with Embodiment 3. The flow chart in FIG. 16 represents an infrared photodetection process equivalent to a one-color method where a detection proportion α, an emissivity e, and a transmittance T are all known.

The flow chart in FIG. 16 includes step S26 in place of steps S24 and S25 of the flow chart in FIG. 15 and is otherwise identical to the flow chart in FIG. 15.

Referring to FIG. 16, upon starting the infrared photodetection process, steps S21 to S23 are sequentially implemented as described above.

Subsequent to step S23, the calculation section 3B plugs the detection proportion α (which has a constant value), the emissivity a (which has a constant value), the transmittance τ (which has a constant value), the detection sensitivity A_{L}, the optical signal component D_{L}, and the radiation spectrum I(λ) represented by equation (1) into equation (8), to calculate the temperature T of the measurement object 30 (step S26), which completes the infrared photodetection process.

Embodiment 3 requires no reference element 12 of Embodiment 1, thereby enabling reducing the size and cost of the infrared photodetection device. In addition, since it is possible to calculate a thermal signal component for each detection element, the thermal signal component can be accurately corrected even when the thermal signal component varies from one detection element to the other.

Besides, Embodiment 3 additionally achieves the various effects described in Embodiment 1.

In Embodiment 3, the operations of the calculation section 3B may be implemented using software. In such a case, the calculation section 3B includes: a CPU (including a computation section), a ROM, and a RAM.

The ROM contains either a program Prog_C including: step S1-2 where the time response of the detection value D_{D} is received from the detection element 11; and steps S23 to S25 shown in FIG. 15 or a program Prog_D including: step S1-2 where the time response of the detection value D_{D} is received from the detection element 11; and steps S23 and S26 shown in FIG. 16. The ROM also contains either the known detection sensitivities A_{L}, A_{R}, and A_{N} or the constant detection proportion α, the constant emissivity ε, the constant transmittance τ, and the constant detection sensitivity A_{L}. The RAM temporarily stores the calculated ratio D_{D}/D_{N} or optical signal component D_{L}.

The CPU retrieves the program Prog_C from the ROM and executes the program Prog_C to calculate the temperature T of the measurement object 30 using the above-described technique. In such a case, the CPU sequentially executes steps S1-2 and S23 to S25. The CPU alternatively retrieves the program Prog_D from the ROM and executes the program Prog_D to calculate the temperature T of the measurement object 30 using the above-described technique. In such a case, the CPU sequentially executes steps S1-2, S23, and S26.

The CPU, which calculates the ratio D_{D}/D_{N} (or the optical signal component D_{L} and the thermal signal component D_{N}) and the temperature T of the measurement object 30, constitutes at least a part of a calculation means. The CPU, which receives the time response of the detection value D_{D}, constitutes at least a part of a reception means.

The program Prog_C (or program Prog_D) may be contained in a storage medium (e.g., CD or DVD) for distribution. In such a case, the computer (CPU) retrieves the program Prog_C (or program Prog_D) from the storage medium and executes the program Prog_C (or program Prog_D) to calculate the temperature of the measurement object 30 using the above-described technique. Accordingly, the CD, DVD, and other like storage media containing the program Prog_C (or program Prog_D) are computer-(CPU-)readable storage media containing the program Prog_C (or program Prog_D).

The description of Embodiment 1 applies to Embodiment 3 unless otherwise mentioned explicitly.

### Embodiment 4

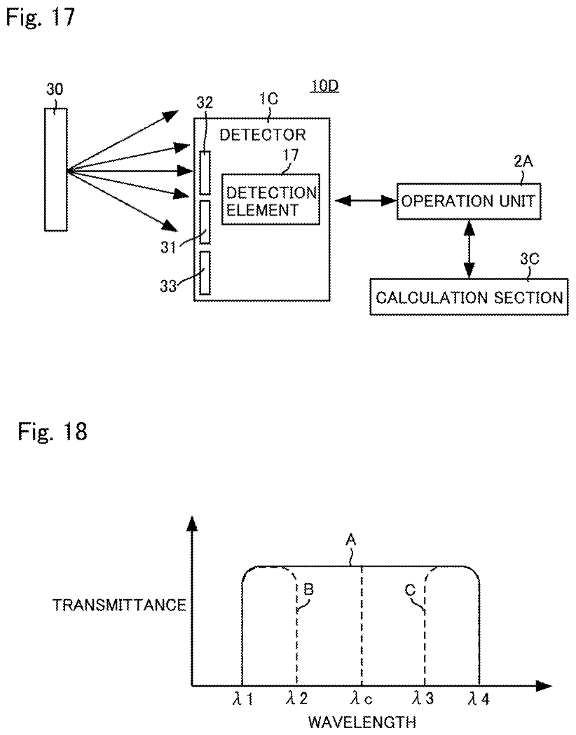

FIG. 17 is a schematic view of an infrared photodetection device in accordance with Embodiment 4. Referring to FIG. 17, an infrared photodetection device 10D in accordance with Embodiment 4 includes a detection unit 1C, an operation unit 2A, and a calculation section 3C.

The detection unit 1C includes a detection element 17 and wavelength filters 31 to 33. The detection element 17 includes, for example, an electromagnetic wave detection element such as a thermopile or a bolometer. The detection element 17 may be either a single element or an imager including a plurality of such elements.

The detection element 17 detects infrared light passing through the wavelength filter 31 and outputs a first detection value obtained upon the detection of the infrared light to the operation unit 2A. The detection element 17 also detects infrared light passing through the wavelength filter 32 and outputs a second detection value obtained upon the detection of the infrared light to the operation unit 2A. The detection element 17 further detects infrared light passing through the wavelength filter 33 and outputs a third detection value obtained upon the detection of the infrared light to the operation unit 2A.

Each wavelength filter 31 to 33 includes, for example, a multilayered interference filter. The wavelength filter 31 to 33 has a transmission range which will be detailed later. The wavelength filter 31 may be disposed on the detection element 17 or realized by utilizing the inherent detection sensitivity of the detection element 17.

The operation unit 2A receives the first detection value, the second detection value, and the third detection value from the detection element 17 and outputs the received first detection value, the received second detection value, and the received third detection value to the calculation section 3C. The operation unit 2A switches between the wavelength filters 31 to 33.

The calculation section 3C receives the first detection value, the second detection value, and the third detection value from the operation unit 2A and calculates the temperature of an object 30 on the basis of the received first detection value, the received second detection value, and the received third detection value using a technique which will be detailed later.

FIG. 18 is a diagram representing a relationship between the transmittance of a wavelength filter and wavelength. Referring to FIG. 18, a wavelength range A is from wavelength λ1 to wavelength λ4 over which infrared light is transmitted. A wavelength range B is from wavelength λ1 to wavelength λ2, lying toward the short wavelength end with respect to a central wavelength λc of the wavelength range A, over which infrared light is transmitted. A wavelength range C is from wavelength λ3 to wavelength λ4, lying toward the long wavelength end with respect to the central wavelength λc of the wavelength range A, over which infrared light is transmitted.

As described here, the wavelength range B is from λ1 to λ2, lying toward the short wavelength end with respect to the central wavelength λc of the wavelength range A and also within the wavelength range A (λ1 to λ4). The wavelength range C is from λ3 to λ4, lying toward the long wavelength end with respect to the central wavelength λc of the wavelength range A and also within the wavelength range A (λ1 to λ4).

The wavelength filter 31 passes infrared light in the wavelength range A. The wavelength filter 32 passes infrared light in the wavelength range B. The wavelength filter 33 passes infrared light in the wavelength range C. Therefore, the first wavelength range corresponds to the wavelength range A, and the second wavelength range corresponds to the wavelength ranges B and C. Here, the wavelength range B and the wavelength range C are the third wavelength range and a fourth wavelength range respectively.

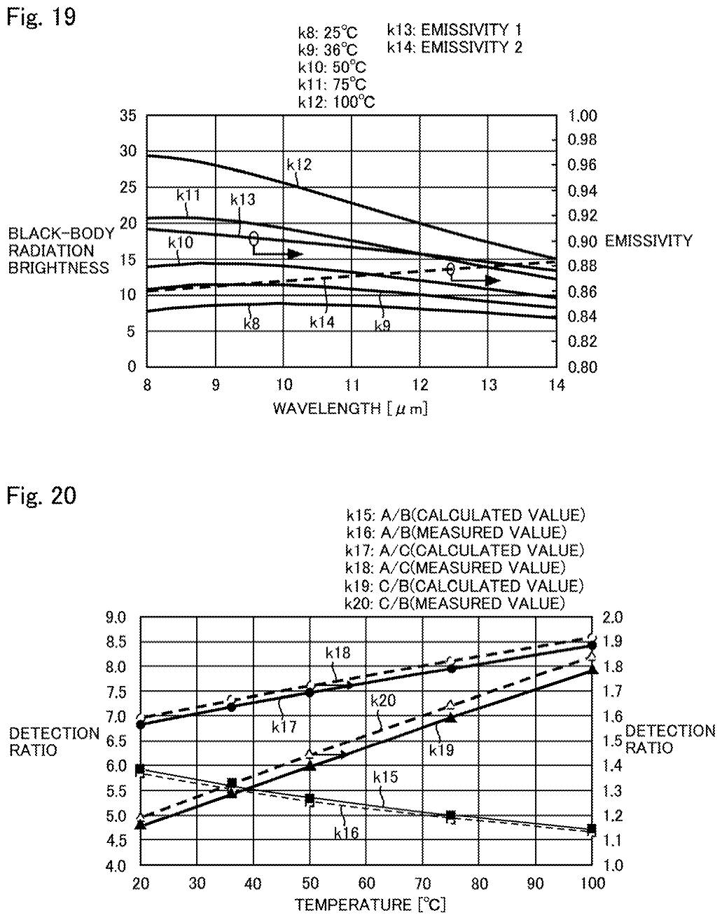

FIG. 19 is a diagram representing a relationship between black-body radiation brightness, emissivity, and wavelength. In FIG. 19, the vertical axis represents black-body radiation brightness and emissivity, and the horizontal axis represents wavelength. Curved lines k8 to k12 represent respective relationships between black-body radiation brightness and wavelength at temperatures of 25° C., 36° C., 50° C., 75° C., and 100° C. Curved lines k13 and k14 represent respective relationships between emissivity and wavelength.

Referring to FIG. 19, the heat radiation of an object exhibits wavelength dependency over a broad infrared region. The emissivity of an object may in some cases be considered constant, but in some cases exhibits wavelength dependency as indicated by curved lines k13 and k14.

The detection intensity detected by the detection element 17 is the product, black-body radiation brightness×detection proportion×emissivity×transmittance, integrated over a range of wavelengths. The black-body radiation brightness is given by equation (1) above representing the Planck equation and is dependent on the temperature of the object. In Embodiment 4, it is assumed that the detection sensitivity of the detection element 17 has no wavelength dependency.

FIG. 20 is a diagram representing a relationship between a detection ratio and temperature. In FIG. 20, the vertical axis represents a detection ratio, and the horizontal axis represents temperature. A/B denotes a ratio RTO_1 (=DV_A/DV_B) of a detection value DV_A obtained when infrared light is detected in the wavelength range A to a detection value DV_B obtained when infrared light is detected in the wavelength range B. A/C denotes a ratio RTO_2 (=DV_A/DV_C) of the detection value DV_A obtained when infrared light is detected in the wavelength range A to a detection value DV_C obtained when infrared light is detected in the wavelength range C. C/B denotes a ratio RTO_3 (=DV_C/DV_B) of the detection value DV_C obtained when infrared light is detected in the wavelength range C to the detection value DV_B obtained when infrared light is detected in the wavelength range B.

Curved line k15 represents calculated values of A/B. Curved line k16 represents measured values of A/B. Curved line k17 represents calculated values of A/C. Curved line k18 represents measured values of A/C. Curved line k19 represents calculated values of C/B. Curved line k20 represents measured values of C/B.

FIG. 20 shows results obtained when the wavelength range A is from 8 to 14 μm, the wavelength range B is from 8 to 9 μm, and the wavelength range C is from 13 to 14 μm.

Referring to FIG. 20, the emissivity is assumed to be constant for calculated values (the emissivity is assumed to have no wavelength dependency). For measured values, the emissivity is dependent on wavelength as indicated by curved line k13 in FIG. 19. The measured values therefore deviate from the calculated values.

Conventionally, C/B is calculated using a two-color method from results for the wavelength range B (=8 to 9 μm) and results for the wavelength range C (=13 to 14 μm), and the temperature of an object is calculated on the basis of thus-calculated C/B (see curved line k19). Refer to the right-side vertical axis in FIG. 20 for C/B (calculated values) represented by curved line k19 and C/B (measured values) represented by curved line k20.

The temperature at the point where the arrow originating at the measured value at 50° C. intersects with a calculated value is the temperature obtained in measurement. In other words, the temperature difference corresponding to the length of the arrow is a temperature error.

The wavelength dependency of emissivity often changes monotonically. Here, the result obtained when the wavelength filter 32 (=wavelength range B) or the wavelength filter 33 (=wavelength range C) is used has a maximum error from a calculated value. For emissivity change 1 (see curved line k13) in FIG. 19, the result obtained when the wavelength filter 33 (=wavelength range C) is used has a maximum error from a calculated value. Accordingly, the two-color method produces similarly large error when a ratio to this result is taken. By obtaining the three sets of results, A/B, A/C, and C/B, A/B, which differs much from the result of C/B, produces a minimum error. Thus, one of the temperatures calculated using A/B and A/C that differs more from the temperature calculated using C/B is calculated as the temperature of the object 30.

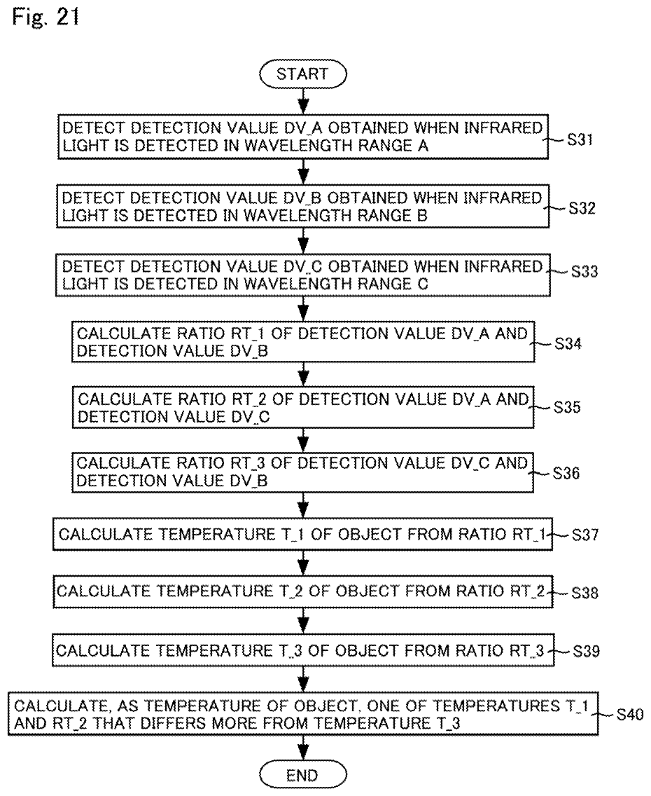

FIG. 21 is a flow chart representing an infrared photodetection process in accordance with Embodiment 4. Referring to FIG. 21, upon starting the infrared photodetection process, the operation unit 2A sets the wavelength filter 31 between the object 30 and the detection element 17. The detection element 17 then detects the detection value DV_A obtained when infrared light is detected in the wavelength range A through the wavelength filter 31 (step S31) and outputs the detected detection value DV_A to the operation unit 2A.

Upon receiving the detection value DV_A from the detection element 17, the operation unit 2A sets the wavelength filter 32 between the object 30 and the detection element 17. The detection element 17 then detects the detection value DV_B obtained when infrared light is detected in the wavelength range B through the wavelength filter 32 (step S32) and outputs the detected detection value DV_B to the operation unit 2A.

Upon receiving the detection value DV_B from the detection element 17, the operation unit 2A sets the wavelength filter 33 between the object 30 and the detection element 17. The detection element 17 then detects the detection value DV_C obtained when infrared light is detected in the wavelength range C through the wavelength filter 33 (step S33) and outputs the detected detection value DV_C to the operation unit 2A.

Upon receiving the detection value DV_C from the detection element 17, the operation unit 2A outputs the detection values DV_A, DV_B, and DV_C to the calculation section 3C.

Upon receiving the detection values DV_A, DV_B, and DV_C from the operation unit 2A, the calculation section 3C calculates a ratio RT_1 (=DV_A/DV_B) of the detection value DV_A and the detection value DV_B (step S34), calculates a ratio RT_2 (=DV_A/DV_C) of the detection value DV_A and the detection value DV_C (step S35), and calculates a ratio RT_3 (=DV_C/DV_B) of the detection value DV_C and the detection value DV_B (step S36).

Thereafter, the calculation section 3C calculates a temperature T_1 of the object 30 from the ratio RT_1 (=DV_A/DV_B) using a two-color method (step S37), calculates a temperature T_2 of the object 30 from the ratio RT_2 (=DV_A/DV_C) using a two-color method (step S38), and calculates a temperature T_3 of the object 30 from the ratio RT_3 (=DV_C/DV_B) using a two-color method (step S39).

Accordingly, the calculation section 3C calculates one of the temperatures RT_1 and RT_2 that differs more from the temperature T_3 as the temperature of the object 30 (step S40), which completes the infrared photodetection process.

In the infrared photodetection process shown in FIG. 21, a so-called “two-color method” whereby temperature is calculated from a ratio of detection values for different wavelength ranges is applied to two wavelength ranges with an overlapping detection wavelength range. The calculated temperature has small error even when emissivity has wavelength dependency, by using both the wavelength range B of the wavelength filter 32 and the wavelength range C of the wavelength filter 33.

In Embodiment 4, the operations of the calculation section 3C may be implemented using software. In such a case, the calculation section 3C includes: a CPU (including a computation section), a ROM, and a RAM.

The ROM contains a program Prog_E including: step S1-3 where the detection values DV_A, DV_B, and DV_C are received from the detection element 17, and steps S34 to S40 shown in FIG. 21. The RAM temporarily stores the calculated ratios RT_1 to RT_3 and the calculated temperatures T_1 to T_3.

The CPU retrieves the program Prog_E from the ROM and executes the program Prog_E to calculate the temperature T of the measurement object 30 using the above-described technique. In such a case, the CPU sequentially executes steps S1-3 and S34 to S40.

The CPU, which calculates the ratios RT_1 to RT_3 and the temperatures T_1 to T_3, constitutes at least a part of a calculation means. The CPU, which receives the detection values DV_A, DV_B, and DV_C, constitutes at least a part of a reception means.

The program Prog_E may be contained in a storage medium (e.g., CD or DVD) for distribution. In such a case, the computer (CPU) retrieves the program Prog_E from the storage medium and executes the program Prog_E to calculate the temperature of the measurement object 30 using the above-described technique. Accordingly, the CD, DVD, and other like storage media containing the program Prog_E are computer-(CPU-)readable storage media containing the program Prog_E.

### Embodiment 5

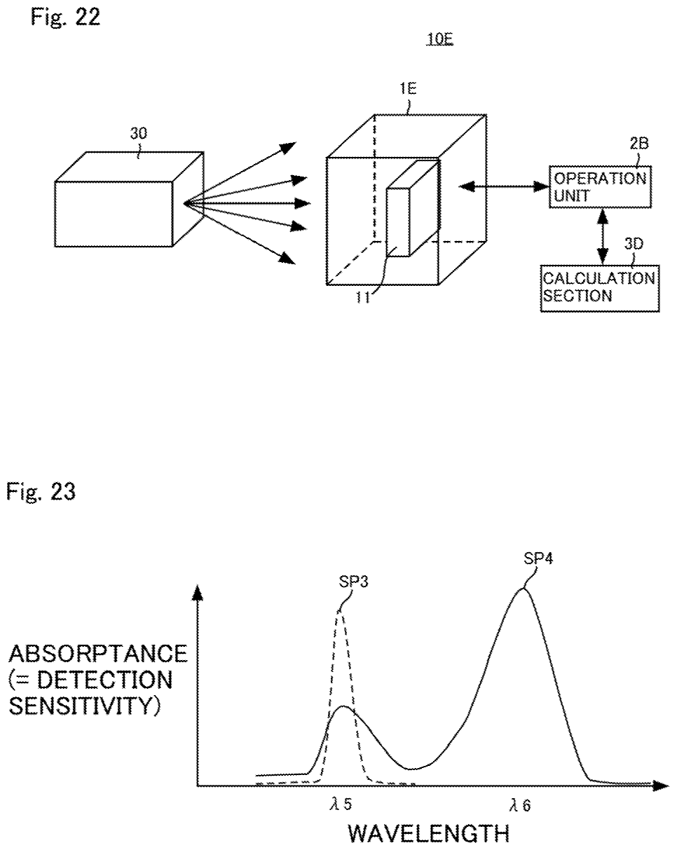

FIG. 22 is a schematic view of an infrared photodetection device in accordance with Embodiment 5. Referring to FIG. 22, an infrared photodetection device 10E in accordance with Embodiment 5 includes: a detection unit IE, an operation unit 2B, and a calculation section 3D.

The detection unit IE includes no reference element 12 in the detection unit 1 shown in FIG. 1 and is otherwise identical to the detection unit 1.

The operation unit 2B applies an application voltage V1 or an application voltage V2 to the detection element 11. The application voltage may be manually or automatically switched between V1 and V2 and may be varied at a time cycle T_{S} beforehand as in, for example, V=(V2−V1)sin(2πt/T_{S})+V1. In such a case, the voltage V has an amplitude V2−V1 and varies with time t between V1 and V2 along a sine curve. The voltage V1 is equal to the voltage V when time t is equal to t₁ (V=(V2−V1)sin(2πₜ₁/T_{S})+V1). The voltage V2 is equal to the voltage V when time t is equal to t₂ (V=(V2−V1)sin(2πt₂/T_{S})+V1).

The operation unit 2B receives, from the detection element 11, a detection spectrum SP1 detected by the detection element 11 under the application voltage V1 and a detection spectrum SP2 detected by the detection element 11 under the application voltage V2 and outputs the received detection spectra SP1 and SP2 to the calculation section 3D.

The calculation section 3D receives the detection spectra SP1 and SP2 from the operation unit 2B and calculates the temperature of the object 30 from the received detection spectra SP1 and SP2 using a technique which will be detailed later.

FIG. 23 is a diagram representing a relationship between the detection sensitivity of the detection element 11 shown in FIG. 22 and wavelength. In FIG. 23, the vertical axis represents absorptance, in other words, detection sensitivity, and the horizontal axis represents wavelength.

Referring to FIG. 23, the detection element 11 detects the detection spectrum SP1 using a detection sensitivity spectrum SP3 under the applied voltage V1 and detects the detection spectrum SP2 using a detection sensitivity spectrum SP4 under the applied voltage V2.

The detection sensitivity spectrum SP3 has a peak wavelength λ5 with infrared light in a wavelength range D being absorbed. The detection sensitivity spectrum SP4 has a peak wavelength λ6 with infrared light in a wavelength range E being absorbed. The detection sensitivity spectrum SP4 has an absorption wavelength range partially overlapping the detection sensitivity spectrum SP3.

The wavelength range D of the detection sensitivity spectrum SP3 corresponds to the wavelength range B of Embodiment 4. The result SP4−(SP3×Hk) of subtraction from the detection sensitivity spectrum SP4 of SP3×Hk, which is a result of multiplication of the detection sensitivity spectrum SP3 and a correction coefficient Hk, corresponds to the wavelength range C of Embodiment 4. Additionally, the result of weighting β×SP3+(1−β)×SP4, which is a sum of the products of the detection sensitivity spectra SP3 and SP4 and a weight coefficient, corresponds to the wavelength range A of Embodiment 4, where β is a real number that satisfies 0<β<1.

Therefore, the temperature of the object 30 can be calculated from the detection sensitivity spectrum SP3, the result of subtraction SP4−(SP3×Hk), and the result of weighting β×SP3+(1−β)×SP4 by using the technique described in Embodiment 4.

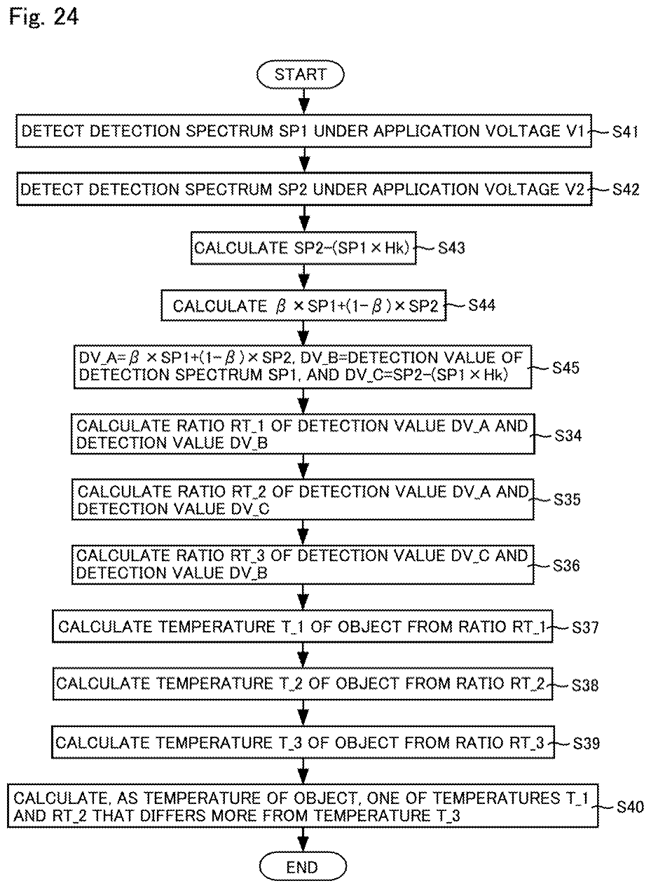

FIG. 24 is a flow chart representing an infrared photodetection process in accordance with Embodiment 5. The flow chart in FIG. 24 includes steps S41 to S45 in place of steps S31 to S33 in the flow chart in FIG. 21 and is otherwise identical to the flow chart in FIG. 21.

Referring to FIG. 24, upon starting the infrared photodetection process, the operation unit 2B applies the voltage V1 to the detection element 11. The detection element 11 then detects the detection spectrum SP1 of infrared light under the applied voltage V1 (step S41) and outputs the detected detection spectrum SP1 to the operation unit 2B.

Upon receiving the detection spectrum SP1 from the detection element 11, the operation unit 2B applies the voltage V2 to the detection element 11. The detection element 11 then detects the detection spectrum SP2 of infrared light under the applied voltage V2 (step S42) and outputs the detected detection spectrum SP2 to the operation unit 2B.

Upon receiving the detection spectrum SP2 from the detection element 11, the operation unit 2B outputs the detection spectra SP1 and SP2 to the calculation section 3D.

Upon receiving the detection spectra SP1 and SP2 from the operation unit 2B, the calculation section 3D calculates the result of subtraction SP2−(SP1×Hk) from the detection spectra SP1 and SP2 and the correction coefficient Hk (step S43). In addition, the calculation section 3D calculates the result of weighting β×SP1+(1−β)×SP2 from the detection spectra SP1 and SP2 and a weight coefficient β (step S44).

Accordingly, the calculation section 3D assigns the result of weighting β×SP1+(1−β)×SP2 to the detection value DV_A, the detection value of the detection spectrum SP1 to the detection value DV_B, and the result of subtraction SP2−(SP1×Hk) to the detection value DV_C (step S45).

Thereafter, the calculation section 3D sequentially executes steps S34 to S40 described in Embodiment 4 to calculate the temperature of the object 30, which completes the infrared photodetection process.

The calculation of the temperature of the object 30 represented by the flow chart in FIG. 24 eliminates the need for wavelength filters and a mechanism for switching between the wavelength filters. The process achieves highly precise calculation of the temperature of the object 30 by using the single detection element 11.

In Embodiment 5, the operations of the calculation section 3D may be implemented using software. In such a case, the calculation section 3D includes: a CPU (including a computation section), a ROM, and a RAM.

The ROM contains a program Prog_F including: step S1-4 where the detection spectra SP1 and SP2 are received from the detection element 11; and steps S43 to S45 and S34 to S40 shown in FIG. 24. The RAM temporarily stores the calculated ratios RT_1 to RT_3 and the calculated temperatures T_1 to T_3.

The CPU retrieves the program Prog_F from the ROM and executes the program Prog_F to calculate the temperature T of the measurement object 30 using the above-described technique. In such a case, the CPU sequentially executes steps S1-4, S43 to S45, and S34 to S40.

The CPU, which calculates the result of weighting β×SP1+(1−β)×SP2, the result of subtraction SP2−(SP1×Hk), the ratios RT_1 to RT_3, and the temperatures T_1 to T_3, constitutes at least a part of a calculation means. The CPU, which receives the detection spectra SP1 and SP2, constitutes at least a part of a reception means.

The program Prog_F may be contained in a storage medium (e.g., CD or DVD) for distribution. In such a case, the computer (CPU) retrieves the program Prog_F from the storage medium and executes the program Prog_F to calculate the temperature of the measurement object 30 using the above-described technique. Accordingly, the CD, DVD, and other like storage media containing the program Prog_F are computer-(CPU-)readable storage media containing the program Prog_F.

The description of Embodiment 1 applies to Embodiment 5 unless otherwise mentioned explicitly.

### Embodiment 6

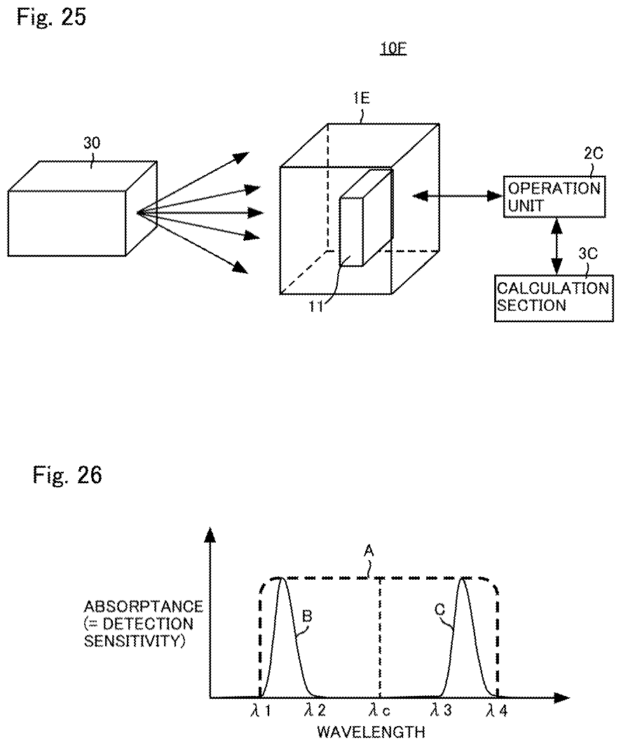

FIG. 25 is a schematic view of an infrared photodetection device in accordance with Embodiment 6. Referring to FIG. 25, an infrared photodetection device 10F in accordance with Embodiment 6 includes an operation unit 2C and a calculation section 3C in place of the operation unit 2B and the calculation section 3D in an infrared photodetection device 10E shown in FIG. 22 and is otherwise identical to the infrared photodetection device 10E.

The operation unit 2C applies a voltage V3 to the detection element 11 to set the detection wavelength range of the detection element 11 to the wavelength range A described in Embodiment 4. The operation unit 2C also applies a voltage V4 to the detection element 11 to set the detection wavelength range of the detection element 11 to the wavelength range B described in Embodiment 4. The operation unit 2C also applies a voltage V5 to the detection element 11 to set the detection wavelength range of the detection element 11 to the wavelength range C described in Embodiment 4.

The operation unit 2C receives the detection value DV_A detected by the detection element 11 under the applied voltage V3 from the detection element 11, receives the detection value DV_B detected by the detection element 11 under the applied voltage V4 from the detection element 11, and receives the detection value DV_C detected by the detection element 11 under the applied voltage V5 from the detection element 11. The operation unit 2C then outputs the detection values DV_A to DV_C to the calculation section 3C.

The calculation section 3C receives the detection values DV_A to DV_C from the operation unit 2C and calculates the temperature of the object 30 from the received detection values DV_A to DV_C by using the technique described in Embodiment 4.

FIG. 26 is a diagram representing a relationship between the detection sensitivity of the detection element 11 shown in FIG. 25 and wavelength. In FIG. 26, the vertical axis represents absorptance, in other words, detection sensitivity, and the horizontal axis represents wavelength.

Referring to FIG. 26, under the applied voltage V3, the infrared light absorption wavelength range of the detection element 11 is set to the wavelength range A described in Embodiment 4. Under the applied voltage V4, the infrared light absorption wavelength range of the detection element 11 is set to the wavelength range B described in Embodiment 4. Under the applied voltage V5, the infrared light absorption wavelength range of the detection element 11 is set to the wavelength range C described in Embodiment 4.

The voltages V3 and V4 may be automatically changed. The voltages V3 and V4 may be varied at a time cycle T_{S} beforehand as in, for example, V=(V4−V3)sin(2πt/T_{S})+V3. In such a case, the voltage V has an amplitude V4-V3 and varies with time t between V3 and V4 along a sine curve. The voltage V3 is equal to the voltage V when time t is equal to t3 (V=(V4−V3)sin(2πt₃/T_{S})+V3). The voltage V4 is equal to the voltage V when time t is equal to t4 (V=(V4−V3)sin(2πt₄/T_{S})+V3).

The detection element 11 then detects the detection value DV_B under the applied voltage V3 and the detection value DV_C under the applied voltage V4. The detection element 11 detects a detection value in increments of ΔV from the voltage V3 to the voltage V4 with a resolution N. In other words, the detection element 11 detects a detection value DV_nΔV under the applied voltage V3+nΔV, where n is an integer from 1 to N−1. The comprehensive sum of DV_B, DV_C, and the sum of DV_nΔV as n goes from 1 to N−1 corresponds to the detection value DV_A for the wavelength range A described in Embodiment 4.

The calculation section 3C can therefore calculate the temperature of the object 30 by using the technique described in Embodiment 4.

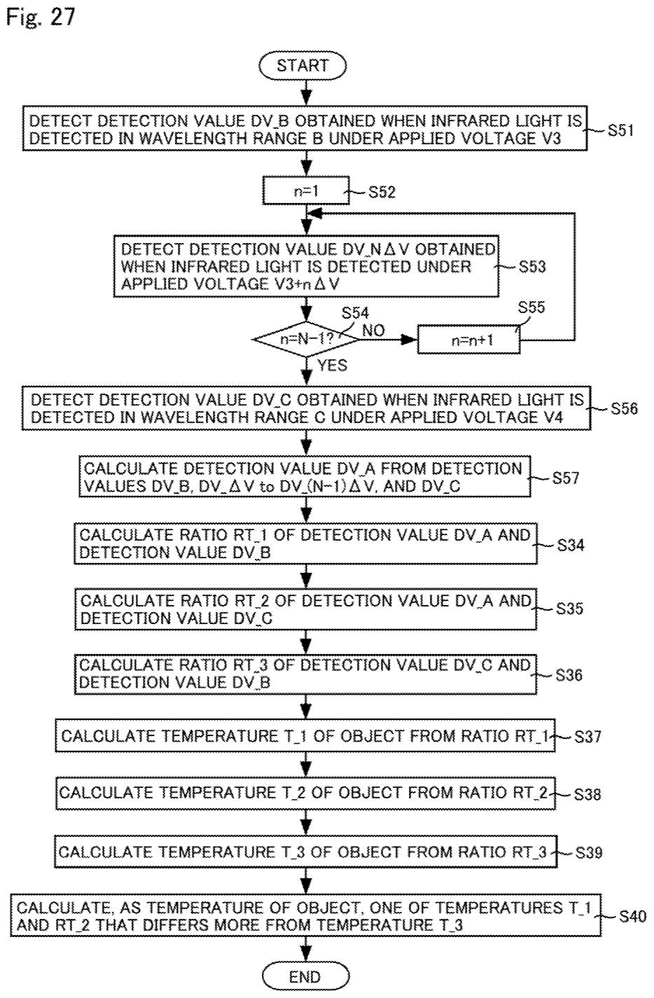

FIG. 27 is a flow chart representing an infrared photodetection process in accordance with Embodiment 6. The flow chart in FIG. 27 includes steps S51 to S57 in place of steps S31, S32, and S33 in the flow chart in FIG. 21 and is otherwise identical to the flow chart in FIG. 21.

Referring to FIG. 27, upon starting the infrared photodetection process, the operation unit 2C applies the voltage V3 to the detection element 11. The detection element 11 then detects the detection value DV_B obtained when infrared light is detected in the wavelength range B under the applied voltage V3 (step S51) and outputs the detected detection value DV_B to the operation unit 2C.

Upon receiving the detection value DV_B from the detection element 11, the operation unit 2C sets n to 1 (step S52) to apply the voltage V3+nΔV to the detection element 11. The detection element 11 then detects the detection value DV_nΔV obtained when infrared light is detected under the applied voltage V3+nΔV (step S53) and outputs the detected detection value DV_nΔV to the operation unit 2C.

Upon receiving the detection value DV_nΔV from the detection element 11, the operation unit 2C determines whether or not n is equal to N−1 (step S54). If it is determined in step S54 that n is not equal to N−1, the operation unit 2C sets n to n+1 (step S55). Thereafter, the process proceeds to step S53 where steps S53 to S55 are repeated until it is determined in step S54 that n=N−1.

If it is determined in step S54 that n=N−1, in other words, if the operation unit 2C receives a detection value DV_(N−1)ΔV from the detection element 11, the operation unit 2C applies the voltage V4 to the detection element 11. The detection element 11 then detects the detection value DV_C obtained when infrared light is detected in the wavelength range C under the applied voltage V4 (step S56) and outputs the detected detection value DV_C to the operation unit 2C.

Upon receiving the detection value DV_C from the detection element 11, the operation unit 2C outputs the detection values DV_B, DV_ΔV to DV_(N−1)ΔV, and DV_C to the calculation section 3C. Upon receiving the detection values DV_B, DV_ΔV to DV_(N−1)ΔV, and DV_C from the operation unit 2C, the calculation section 3C calculates the detection value DV_A, which is a sum of the received detection values DV_B, DV_ΔV to DV_(N−1)ΔV, and DV_C (step S57).

To obtain the sum here, the detection values DV_B, DV_ΔV to DV_(N−1)ΔV, and DV_C are added up after the detection values DV_ΔV to DV_(N−1)ΔV are multiplied by respective coefficients in such a manner as to match with the detection value for the wavelength range A. If the shift width of the detection wavelength of the detection element 11 when the voltage applied to the detection element 11 has changed by a voltage ΔV is more than the shift width of the detection wavelength before the voltage applied to the detection element 11 is changed by the voltage ΔV, the calculation section 3C calculates a sum of the detection values DV_B, DV_ΔV to DV_(N−1)ΔV, and DV_C after multiplying the detection values DV_ΔV to DV_(N−1)ΔV by respective coefficients that are larger than 1. On the other hand, if the shift width of the detection wavelength of the detection element 11 when the voltage applied to the detection element 11 has changed by the voltage ΔV is less than the shift width of the detection wavelength before the voltage applied to the detection element 11 is changed by the voltage ΔV, the calculation section 3C calculates a sum of the detection values DV_B, DV_ΔV to DV_(N−1)ΔV, and DV_C after multiplying the detection values DV_ΔV to DV_(N−1)ΔV by respective coefficients that are smaller than 1. Suitable coefficients can be calculated if the shift width of the detection wavelength of the detection element 11 when the voltage has changed by ΔV is measured beforehand and stored in the calculation section 3C in the form of a table.

Then, subsequent to step S57, the calculation section 3C also sequentially executes steps S34 to S40 described above to calculate the temperature of the object 30.

The calculation of the temperature of the object 30 represented by the flow chart in FIG. 27 eliminates the need for wavelength filters and a mechanism for switching between the wavelength filters. The process achieves the same various effects as in Embodiment 4.

In Embodiment 6, the operations of the calculation section 3C may be implemented using software. In such a case, the calculation section 3C includes: a CPU (including a computation section), a ROM, and a RAM.

The ROM contains a program Prog_G including: step S1-5 where the detection values DV_B, DV_nΔV (n=1 to N−1), and DV_C are received from the detection element 11; and steps S34 to S40 shown in FIG. 27. The RAM temporarily stores the calculated ratios RT_1 to RT_3 and the calculated temperatures T_1 to T_3.

The CPU retrieves the program Prog_G from the ROM and executes the program Prog_G to calculate the temperature T of the measurement object 30 using the above-described technique. In such a case, the CPU sequentially executes steps S1-5 and S34 to S40.

The CPU, which calculates the ratios RT_1 to RT_3 and the temperatures T_1 to T_3, constitutes at least a part of a calculation means. The CPU, which receives the detection values DV_B, DV_nΔV (n=1 to N−1), and DV_C, constitutes at least a part of a reception means.

The program Prog_G may be contained in a storage medium (e.g., CD or DVD) for distribution. In such a case, the computer (CPU) retrieves the program Prog_G from the storage medium and executes the program Prog_G to calculate the temperature of the measurement object 30 using the above-described technique. Accordingly, the CD, DVD, and other like storage media containing the program Prog_G are computer-(CPU-)readable storage media containing the program Prog_G.

The description of Embodiments 1 and 5 applies to Embodiment 6 unless otherwise mentioned explicitly.

Embodiments 1 and 2 described earlier describe that the ratio D_{D}/D_{R} is calculated from the detection values D_{D} and D_{R} detected respectively using the second wavelength range and the first wavelength range which is broader than the second wavelength range. Embodiments 1 and 2 also describe that the temperature T of the measurement object 30 is calculated by plugging into equation (11) the calculated ratio D_{D}/D_{R}, the radiation spectrum I(λ) represented by equation (1), and the detection sensitivities A_{L}, A_{R}, and A_{N}.

Embodiment 3 described earlier describes that the optical signal component D_{L} and the thermal signal component D_{N} are calculated from the time response of the detection value D_{D}, that D_{D} is determined from the calculated optical signal component D_{L} and the calculated thermal signal component D_{N} to calculate the ratio D_{D}/D_{N}, and that the temperature T of the measurement object 30 is calculated by plugging the calculated ratio D_{D}/D_{N}, the radiation spectrum I(λ) represented by equation (1), and the detection sensitivities A_{L}, A_{R}, and A_{N} into an equation obtained from equation (11) by replacing D_{D}/D_{R} with D_{D}/D_{N} therein. The optical signal component D_{L} is a signal component for the second wavelength range described in Embodiments 1 and 2. The thermal signal component D_{N} is a signal component for the first wavelength range described in Embodiments 1 and 2. Accordingly, the temperature of the object 30 is calculated using the signal component for the second wavelength range and the signal component for the first wavelength range in Embodiment 3.

Embodiments 4 and 5 describe that the temperature of the object 30 is calculated from the detection values DV_A, DV_B, and DV_C detected respectively for the wavelength range A, the wavelength range B, and the wavelength range C. The wavelength range B is from wavelength λ1 to wavelength λ2, lying toward the short wavelength end with respect to a central wavelength kc of the wavelength range A, over which infrared light is transmitted. The wavelength range C is from wavelength λ3 to wavelength λ4, lying toward the long wavelength end with respect to the central wavelength λc of the wavelength range A, over which infrared light is transmitted.

Embodiment 5 describes that the temperature of the object 30 is calculated from the detection values detected for a wavelength range corresponding to the wavelength range A, a wavelength range corresponding to the wavelength range B, and a wavelength range corresponding to the wavelength range C.

Therefore, Embodiments 1 to 6 share a common feature that the temperature of the object 30 is calculated from infrared light detection values detected for two different, but partially overlapping wavelength ranges.

Accordingly, the present invention, in an embodiment thereof, is directed to an infrared photodetection device including: a detection unit including a detection element configured to detect infrared light in a first wavelength range and detect infrared light in a second wavelength range lying within the first wavelength range and toward a short wavelength end or a long wavelength end with respect to a central wavelength of the first wavelength range; and a calculation unit configured to receive, from the detection unit, a first detection value obtained when infrared light is detected in the first wavelength range by the detection element and a second detection value obtained when infrared light is detected in the second wavelength range by the detection element, calculate A ratio of the received first and second detection values, and calculate temperature of an object from the calculated ratio.

The present invention, in an embodiment thereof, is directed to an infrared photodetection process including: a first step of a detection element detecting infrared light in a first wavelength range and detecting infrared light in a second wavelength range lying within the first wavelength range and toward a short wavelength end or a long wavelength end with respect to a central wavelength of the first wavelength range; and a second step of receiving a first detection value obtained when infrared light is detected in the first wavelength range by the detection element and a second detection value obtained when infrared light is detected in the second wavelength range by the detection element, calculating a ratio of the received first and second detection values, and calculating temperature of an object from the calculated ratio.

The present invention, in an embodiment thereof, is directed to a computer program for causing a computer to calculate temperature of an object from a first detection value obtained when infrared light is detected in a first wavelength range by a detection element and a second detection value obtained when infrared light is detected in a second wavelength range by the detection element, the second wavelength range lying within the first wavelength range and toward a short wavelength end or a long wavelength end with respect to a central wavelength of the first wavelength range, the computer program causing the computer to implement: a first step of a reception means receiving the first detection value and the second detection value; a second step of a calculation means calculating a ratio of the first and second detection values from the first and second detection values received in the first step; and a third step of the calculation means calculating the temperature of the object from the calculated ratio.

Each calculation section 3, 3A, 3B, 3C, and 3D constitutes at least a part of a calculation unit in an embodiment of the present invention.

The embodiments and examples disclosed herein are for illustrative purposes only in every respect and provide no basis for restrictive interpretations. The scope of the present invention is defined only by the claims and never bound by the embodiments or examples. Those modifications and variations that may lead to equivalents of claimed elements are all included within the scope of the invention.

### INDUSTRIAL APPLICABILITY

This invention is applicable to infrared photodetection devices, infrared photodetection processes, computer programs, and computer-readable storage media containing such a computer program.

1-20. (canceled)

21. An infrared photodetection device comprising:
a detection unit including at least one detection element configured to detect a first detection value by infrared light in a first wavelength range and a second detection value by infrared light in a second wavelength range lying within the first wavelength range; and
a calculation unit including a computation section capable of calculating temperature of an object from the first detection value and the second detection value.

22. The infrared photodetection device according to claim 21, wherein
the at least one detection element includes a first detection element configured to detect the first detection value by infrared light in the first wavelength range, and
the infrared photodetection device further comprises a reflector on an infrared-light-incident side of the first detection element so as to face the first detection element, the reflector being configured to reflect infrared light incident to the first detection element.

23. The infrared photodetection device according to claim 22, wherein
the at least one detection element further includes a second detection element configured to detect the second detection value by infrared light in the second wavelength range, and
the infrared photodetection device further comprises a heat conductor in contact with the first and second detection elements.

24. The infrared photodetection device according to claim 22, wherein
the at least one detection element further includes a second detection element configured to detect the second detection value by infrared light in the second wavelength range, and
the infrared photodetection device further comprises an absorber in contact with the first and second detection elements.

25. The infrared photodetection device according to claim 21, wherein the first detection value is a thermal signal component, and the second detection value is an optical signal component.

26. The infrared photodetection device according to claim 21, wherein the calculation unit calculates a thermal signal component as the first detection value and an optical signal component as the second detection value from a time response of a detection value detected by the at least one detection element and calculates the temperature of the object from the calculated optical signal component and the calculated thermal signal component.

27. The infrared photodetection device according to claim 22, wherein the calculation unit calculates a ratio of the first and second detection values and calculates the temperature of the object from the calculated ratio.

28. An infrared photodetection device comprising:
a detection unit including a detection element configured to detect infrared light in a first wavelength range, detect infrared light in a third wavelength range lying within the first wavelength range, the third wavelength range having a central wavelength toward a short wavelength end with respect to a central wavelength of the first wavelength range, and detect infrared light in a fourth wavelength range lying within the first wavelength range, the fourth wavelength range having a central wavelength toward a long wavelength end with respect to the central wavelength of the first wavelength range; and
a calculation unit including a computation section capable of calculating temperature of an object from a first detection value that is an infrared light detection value detected in the first wavelength range by the detection element, a third detection value that is an infrared light detection value detected in the third wavelength range by the detection element, and a fourth detection value that is an infrared light detection value detected in the fourth wavelength range by the detection element, wherein
the calculation unit calculates a first ratio obtained by dividing the first detection value by the third detection value, a second ratio obtained by dividing the first detection value by the fourth detection value, and a third ratio obtained by dividing the fourth detection value by the third detection value and calculates, as the temperature of the object, one of a first temperature of the object calculated from the first ratio and a second temperature of the object calculated from the second ratio that differs more from a third temperature of the object calculated from the third ratio.

29. The infrared photodetection device according to claim 22, wherein the first wavelength range lies within an atmospheric window.

30. The infrared photodetection device according to claim 29, wherein the first wavelength range lies within any one of wavelength ranges of 3.4 to 4.2 μm, 4.4 to 5.5 μm, and 8 to 14 μm.

31. The infrared photodetection device according to claim 22, wherein the first wavelength range is a transmission wavelength range of an optical element disposed between the object and the detection unit.

32. The infrared photodetection device according to claim 28, wherein the detection unit further includes: a first optical filter for detecting the first wavelength range; a second optical filter for detecting the third wavelength range; and a third optical filter for detecting the fourth wavelength range.

33. The infrared photodetection device according to claim 22, wherein the detection element includes a quantum-dot layer or a quantum-well layer.

34. The infrared photodetection device according to claim 33, wherein the infrared photodetection device selects either the second wavelength range or the third wavelength range and the fourth wavelength range by applying a voltage to the detection element.

35. The infrared photodetection device according to claim 22, wherein
the detection element includes:
a first detection element configured to detect infrared light in the first wavelength range; and
either a second detection element configured to detect infrared light in the second wavelength range or a third detection element configured to detect infrared light in the third wavelength range and a fourth detection element configured to detect infrared light in the fourth wavelength range, and
at least the first detection element is a thermal element.

36. The infrared photodetection device according to claim 33, wherein the second detection element has a function identical to a function of the first detection element.

37. An infrared photodetection process comprising:
a first step of a detection element detecting infrared light in a first wavelength range and detecting infrared light in a second wavelength range lying within the first wavelength range, the second wavelength range having a central wavelength toward a short wavelength end or a long wavelength end with respect to a central wavelength of the first wavelength range; and
a second step of receiving a first detection value obtained when infrared light is detected in the first wavelength range by the detection element and a second detection value obtained when infrared light is detected in the second wavelength range by the detection element, calculating a ratio of the received first and second detection values, and calculating temperature of an object from the calculated ratio.

38. The infrared photodetection device according to claim 25, wherein the first wavelength range lies within any one of wavelength ranges of 3.4 to 4.2 μm, 4.4 to 5.5 μm, and 8 to 14 μm.

39. The infrared photodetection device according to claim 25, wherein the first wavelength range is a transmission wavelength range of an optical element disposed between the object and the detection unit.

40. The infrared photodetection device according to claim 25, wherein the detection element includes a quantum-dot layer or a quantum-well layer.
